(19) United States
(12) Patent Application Publication
(10) Pub. No.: US 2014/0256152 A1
(43) Pub. Date: Sep. 11, 2014

(54) SUBSTRATE PROCESSING APPARATUS, SUBSTRATE PROCESSING METHOD, METHOD OF MANUFACTURING SEMICONDUCTOR DEVICE AND RECORDING MEDIUM

(71) Applicant: Hitachi Kokusai Electric Inc., Tokyo (JP)

(72) Inventor: Arito Ogawa, Toyama-shi (JP)

(73) Assignee: HITACHI KOKUSAI ELECTRIC INC., Tokyo (JP)

(21) Appl. No.: 14/350,723

(22) PCT Filed: Sep. 21, 2012
(86) PCT No.: PCT/JP2012/074272

§ 371 Date: Apr. 9, 2014

(30) Foreign Application Priority Data
Oct. 11, 2011 (JP) 2011-223819

(51) Int. Cl. H01L 21/02; H01L 21/285

(52) U.S. Cl. CPC H01L 21/0228; H01L 21/28556
USPC 438/758; 118/704

(57) ABSTRACT

A substrate processing apparatus comprising: a processing chamber that can accommodate a plurality of substrates, the interior of which is divided into a plurality of zones; a gas supply system that supplies a first reactive gas, a second reactive gas, and an inert gas to each of the plurality of zones; and an exhaust system for removing the gas from the zones. A thin film is formed on the substrates in the zones by repeatedly executing a plurality of steps in relation to the zones, these steps include the following: a first reactive gas supply step; a first purge step; a second reactive gas supply step; and a second purge step. While the film is being formed, a control unit controls the gas supply system and the gas exhaust system so that the steps performed in the plurality of zones at the same time are different from one another.

This U.S. non-provisional patent application claims priority under 35 U.S.C. §119 of Japanese Patent Application No. 2011-223819 filed on Oct. 11, 2011 in the Japanese Patent Office and International Application No. PCT/JP2012/074272 filed on Sep. 21, 2012, the entire contents of which are hereby incorporated by reference.

### FIELD OF THE INVENTION

The present invention relates to a substrate processing apparatus for forming a thin film on a substrate such as a wafer, a substrate processing method, a method of manufacturing a semiconductor device, and a non-transitory computer-readable recording medium. For example, the present invention relates to a substrate processing apparatus for forming an insulating film or a metal film in a process included in a process of manufacturing a semiconductor device, such as a large-scale integrated circuit (LSI), a substrate processing method, a method of manufacturing a semiconductor device, and a non-transitory computer-readable recording medium.

### BACKGROUND OF THE INVENTION

A process of manufacturing a metal-oxide-semiconductor field effect transistor (MOSFET) is an example of a process that may be included in a process of manufacturing a semiconductor device (device). As integration degrees and performances of MOSFETs become higher, various types of insulating films or metal films have been considered to be applied to the process of manufacturing a MOSFET. For example, a titanium nitride (TiN) film formed using titanium tetrachloride (TiCl₄) and ammonia (NH₃) may be considered as a metal film; and a hafnium oxide (HfO₂) film formed using tetrakis(ethylmethylamino)hafnium (TEMAH) and either ozone (O₃) or H₂O, a zirconium oxide (ZrO₂) film formed using tetrakis(ethylmethylamino)zirconium (TEMAZ) and ozone (O₃), etc. may be considered as an insulating film.

In the present disclosure, the term ‘metal film’ means a film formed of a conductive material including metal atoms, i.e., a conductive metal-containing film. Examples of the conductive metal-containing film include not only a conductive metal film formed of a metal but also a conductive metal nitride film, a conductive metal oxide film, a conductive metal oxynitride film, a conductive metal carbide film (metal carbide film), a conductive metal carbonitride film, a conductive metal composite film, a conductive metal alloy film, a conductive metal silicide film, etc. Also, a TiN film, a TaN film, an HfN film, and a ZrN film are examples of the conductive metal nitride film. A TiC film is an example of the conductive metal carbide film. A TiCN film is an example of the conductive metal carbonitride film. A TiAlN film is an example of the conductive metal composite film. Also, an alternate supply method of alternately supplying a plurality of types of gases is more frequently used as a film-forming technique than a simultaneous supply method of simultaneously supplying a plurality of types of gases, in terms of reducing a heat load or applying a three-dimensional (3D) device structure.

A film-forming sequence according to the related art in which the alternate supply method is used to form a film is illustrated in FIG. 6. As illustrated in FIG. 6, when the alternate supply method is used, a film is generally formed by repeatedly performing a cycle including four processes: (1) a process of supplying a first reactive gas 61 which is a precursor, (2) a first purge process of discharging the first reactive gas 61 using a purge gas 62, (3) a process of supplying a second reactive gas 63 which is an oxidizing gas or a reducing gas, and (4) a second purge process of discharging the second reactive gas 63 using a purge gas 64.

FIG. 7 is a diagram illustrating an atmosphere in a process furnace when the film-forming sequence according to the related art is performed using, for example, a longitudinal film-forming apparatus. FIG. 7 is a vertical cross-sectional view of a process furnace, in which a boat 217 in which a plurality of wafers 202 are stacked is loaded into a reaction tube 503 having a roughly cylindrical shape and a gas is supplied into the reaction tube 503 via a gas nozzle 531 and exhausted from an exhaust pipe 271. First, referring to (a) of FIG. 7, the first reactive gas 61 is supplied via the gas nozzle 531. Referring to (b) of FIG. 7, the purge gas 62 is supplied via the gas nozzle 531 and the first reactive gas 61 is discharged using the purge gas 62. Then, referring to (c) of FIG. 7, the second reactive gas 63 is supplied via the gas nozzle 531. Thereafter, referring to (d) of FIG. 7, the purge gas 64 is supplied via the gas nozzle 531 and the second reactive gas 63 is discharged using the purge gas 64.

In this case, since appropriate reactions need to occur in the process of supplying the first reactive gas (precursor) 61 and the process of supplying the second reactive gas (oxidizing/reducing gas) 63, the first and second reactive gases 61 and 63 need to be supplied in sufficient amounts. A feed rate of each of the first and second reactive gases 61 and 63 depends on an exposure rate that is a product of a gas feed rate per unit time and a supply time. Here, the supply time needs to be decreased when the feed rate per unit time is high, and to be increased when the feed rate per unit time is low. Thus, when a film is formed using a batch furnace, e.g., a longitudinal film-forming apparatus, it is difficult to increase the feed rate per unit time since a chamber capacity is high and the number of wafers is large. As a result, it takes considerable time to perform the process of supplying the precursor or the process of supplying the oxidizing/reducing gas, thereby lowering the throughput.

Patent document 1 below discloses a technique of forming a thin film on a substrate to a desired thickness by repeatedly performing a step including a process of supplying first reactive species into a process chamber in a longitudinal film-forming apparatus, a purge process of removing residual first active species from the process chamber, a process of supplying second reactive species into the process chamber, and a purge process of removing residual second active species from the process chamber.

### RELATED ART DOCUMENT

### Patent Document

1. Japanese Patent Application Publication No. 2006-269532

### DISCLOSURE OF THE INVENTION

### Problems to be Solved by the Invention

As described above, when a film is formed by alternately supplying a plurality of types of reactive gases using a conventional longitudinal film-forming apparatus, it takes considerable time to perform a process of supplying a first reactive gas or a process of supplying a second reactive gas. Thus, it is not easy to improve the throughput.

It is an object of the present invention to provide a substrate processing apparatus capable of reducing a time required to perform a process of supplying a first reactive gas or a process of supplying a second reactive gas so as to improve the throughput, a substrate processing method performed using the substrate processing apparatus, a method of manufacturing a semiconductor device, and a non-transitory computer-readable recording medium.

### Means for Solving the Problems

According to one aspect of the present invention, there is provided a substrate processing apparatus including: a process chamber divided into a plurality of zones and configured to accommodate a plurality of substrates; a gas supply system configured to supply a first reactive gas, a second reactive gas and an inert gas into each of the plurality of zones of the process chamber; a gas exhaust system configured to exhaust a gas from each of the plurality of zones; and a control unit configured to control the gas supply system and the gas exhaust system to perform a cycle repeatedly in each of the plurality of zones of the process chamber accommodating the plurality of substrates so as to form thin films on the plurality of substrates in each of the plurality of zones, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein the steps performed in the plurality of zones at the same time are different from one another.

According to another aspect of the present invention, there is provided substrate processing method including: (a) accommodating a plurality of substrates in a process chamber divided into a plurality of zones; and (b) forming a thin film on the plurality of substrates in each of the plurality of zones by performing a cycle repeatedly in each of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein the steps performed in the plurality of zones at the same time are different from one another in the step (b).

According to still another aspect of the present invention, there is provided a method of manufacturing a semiconductor device, the method including: (a) accommodating a plurality of substrates in a process chamber divided into a plurality of zones; and (b) forming a thin film on the plurality of substrates in each of the plurality of zones by performing a cycle repeatedly the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein steps performed in the plurality of zones at the same time are different from one another in the step (b).

According to yet another aspect of the present invention, there is provided a non-transitory computer-readable recording medium storing a program that causes a computer to perform: (a) accommodating a plurality of substrates in a process chamber; divided into a plurality of zones; and (b) forming a thin film on the plurality of substrates in each of the plurality of zones by performing a cycle repeatedly in each of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein the steps performed in the plurality of zones at the same time are different from one another in the sequence (b).

### Effects of the Invention

According to the one or more aspects of the present invention, it is possible to reduce a time required to perform a process of supplying a first reactive gas or a process of supplying a second reactive gas, thus improving the throughput.

### BRIEF DESCRIPTION OF THE DRAWINGS

FIG. 1 is a side cross-sectional view of a process furnace according to an embodiment of the present invention.

FIG. 2 is a cross-sectional view (horizontal cross-sectional view) taken along line A-A of FIG. 1.

FIG. 3 illustrates a film-forming sequence according to an embodiment of the present invention.

FIG. 4 is a diagram illustrating an atmosphere in a process furnace in a film-forming sequence according to an embodiment of the present invention.

FIG. 5 is a table showing a film-forming sequence according to an embodiment of the present invention.

FIG. 6 illustrates a film-forming sequence according to the related art.

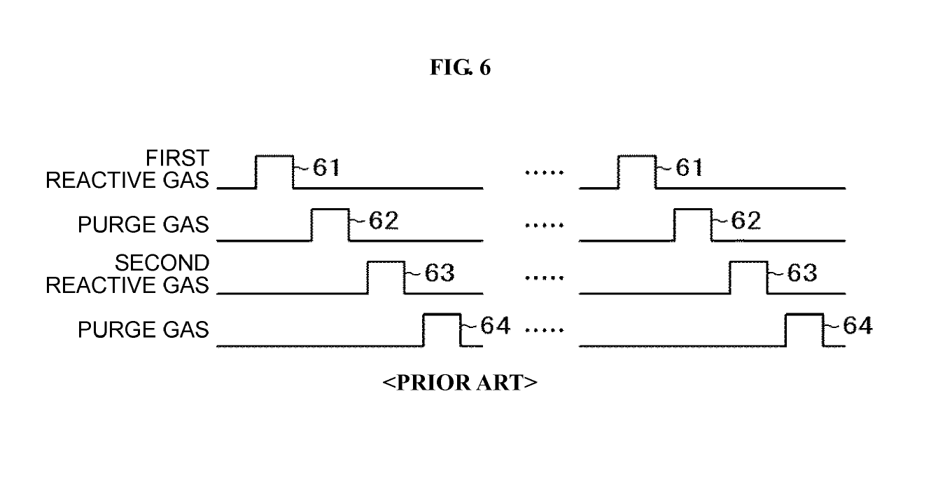

FIG. 7 is a diagram illustrating an atmosphere in a process furnace in a film-forming sequence according to the related art.

FIG. 8 is a block diagram of a control unit according to an embodiment of the present invention.

FIG. 9 is a diagram illustrating an atmosphere in a process furnace in a film-forming sequence according to another embodiment of the present invention.

### DETAILED DESCRIPTION OF THE PREFERRED EMBODIMENTS

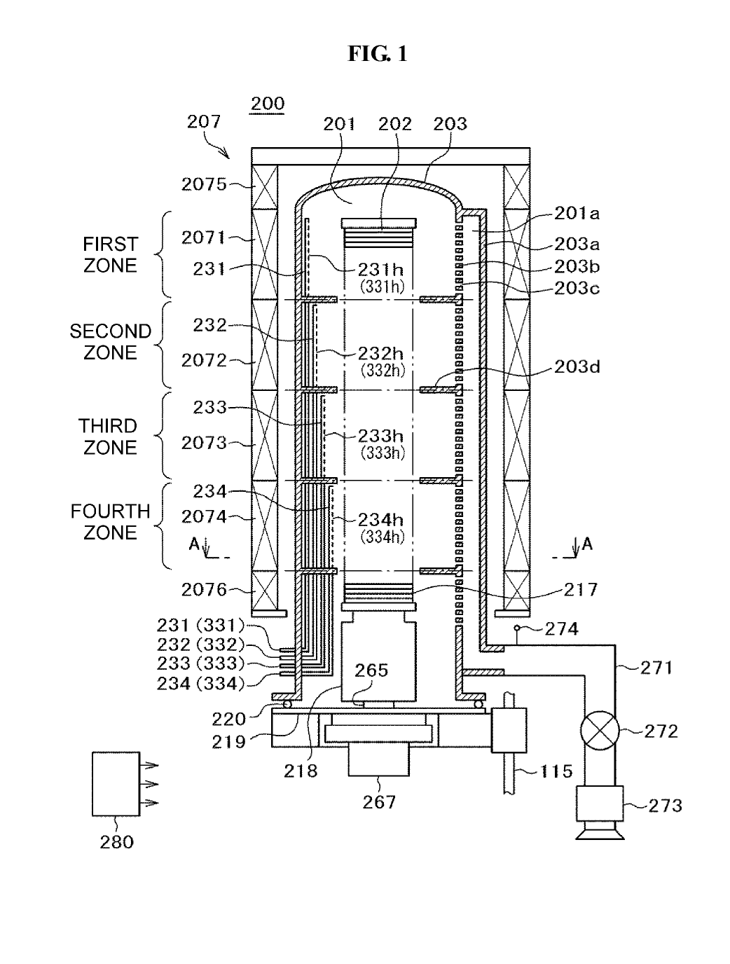

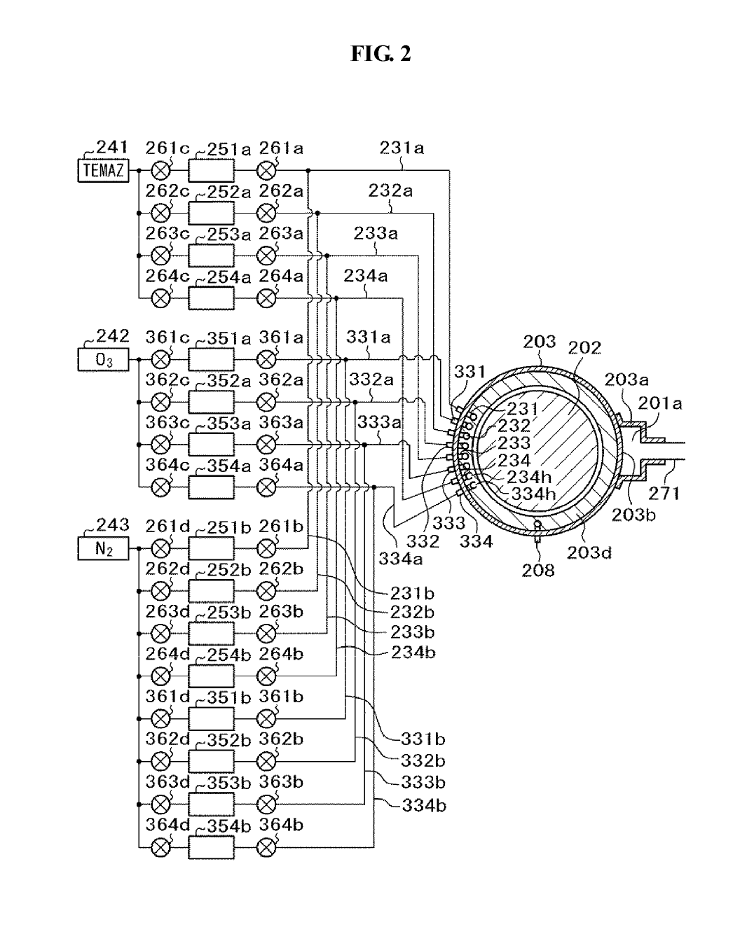

Hereinafter, exemplary embodiments of the present invention will be described with reference to the accompanying drawings. FIG. 1 is a schematic configuration diagram of a longitudinal process furnace 200 included in a substrate processing apparatus according to an embodiment of the present invention, in which a cross-sectional view of a portion of the process furnace 200 is illustrated. FIG. 2 is a cross-sectional view (horizontal cross-sectional view) taken along line A-A of the portion of the process furnace 200 of FIG. 1. As illustrated in FIG. 1, the process furnace 200 includes a heater 207 (including six zone heaters 2071 to 2076) serving as a heating source (heating means). The heater 207 has a cylindrical shape and is vertically installed by being supported by a heater base (not shown) serving as a retaining plate. The heater 207 is a resistance-heating type heater (a heat source using resistance heating), and is configured to heat wafers 202 accommodated in a process chamber 201 (which will be described below) to a predetermined temperature. The heater 207 is divided into the six zone (region) heaters 2071 to 2076, and the six zone heaters 2071 to 2076 are connected to a controller 280 to individually perform temperature control.

As illustrated in FIG. 1, the inside of the process chamber 201 is divided into at least four process zones, e.g., first to fourth zones, from top to bottom. The first to fourth zones are regions in which the wafers 202 are placed to process the wafers 202, and are mainly heated by the first zone heater 2071, the second zone heater 2072, the third zone heater 2073, and the fourth zone heater 2074, respectively. Auxiliary heating regions in which no wafers 202 are placed are installed above the first zone and below the fourth zone, and heated by a first auxiliary heater 2075 and a second auxiliary heater 2076, respectively. Also, dummy wafers are mounted on a portion of a boat 217 corresponding to the second auxiliary heater 2076 rather than wafers for products. Also, such dummy wafers are mounted on a portion of the boat 217 corresponding to an upper portion of the first zone heater 2071, if needed.

In the heater 207, a reaction tube 203 is provided in a concentric shape with the heater 207. The reaction tube 203 is formed of a heat-resistant material, e.g., quartz (SiO₂) or silicon carbide (SiC), and has a cylindrical shape, the upper end of which is closed and the lower end of which is open. The process chamber (reaction chamber) 201 is formed in a hollow tubular portion of the reaction tube 203, and configured to accommodate the wafers 202 serving as substrates such that the wafers 202 are vertically arranged in a horizontal posture and in multiple stages using the boat 217 which will be described below. A reaction container (process container) is formed with the reaction tube 203.

Next, a gas supply system will be described. The gas supply system is configured with a first reactive gas supply system, a second reactive gas supply system, a first inert gas supply system, and a second inert gas supply system which will be described below. As illustrated in FIG. 1, in the reaction tube 203, first reactive gas supply nozzles 231 to 234 configured to supply a first reactive gas, and second reactive gas supply nozzles 331 to 334 configured to supply a second reactive gas (see FIG. 2) are installed to horizontally pass through lower side walls of the reaction tube 203. The first reactive gas supply nozzles 231 to 234 and the second reactive gas supply nozzles 331 to 334 are installed in an arc-shaped space between inner walls of the reaction tube 203 forming the process chamber 201 and the wafers 202 to move upward from lower inner walls of the reaction tube 203 in a direction in which the wafers 202 are stacked. That is, the first reactive gas supply nozzles 231 to 234 and the second reactive gas supply nozzles 331 to 334 are installed along a wafer arrangement region in which the wafers 202 are arranged, in a region that horizontally surrounds the wafer arrangement region at sides of the wafer arrangement region. In the first reactive gas supply nozzles 231 to 234 and the second reactive gas supply nozzles 331 to 334, the nozzles 231 and 331 have the same shape, the nozzles 232 and 332 have the same shape, the nozzles 233 and 333 have the same shape, and the nozzles 234 and 334 have the same shape. Each of these nozzles is configured as an L-shaped long nozzle, and includes a horizontal portion passing through lower sidewalls of the reaction tube 203 and a vertical portion vertically moving at least from one end of the wafer arrangement region toward the other end thereof. For convenience of illustration, FIG. 1 illustrates one of the nozzles 231 and 331, one of the nozzles 232 and 332, one of the nozzles 233 and 333, and one of the nozzles 234 and 334. Also, a manifold formed of a metal may be installed below the reaction tube 203 to support the reaction tube 203, and these nozzles may be installed to pass through sidewalls of the manifold. As described above, a furnace port portion of the process furnace 200 may be formed of a metal and these nozzles may be installed at the furnace port portion formed of a metal.

As illustrated in FIG. 1, the first reactive gas supply nozzle 231 is elongated to the upper portion of the first zone, the first reactive gas supply nozzle 232 is elongated to an upper portion of the second zone, the first reactive gas supply nozzle 233 is elongated to an upper portion of the third zone, and the first reactive gas supply nozzle 234 is elongated to an upper portion of the fourth zone. A plurality of gas supply holes 231h are formed in side surfaces of the first reactive gas supply nozzle 231 in the first zone, a plurality of gas supply holes 232h are formed in side surfaces of the first reactive gas supply nozzle 232 in the second zone, a plurality of gas supply holes 233h are formed in side surfaces of the first reactive gas supply nozzle 233 in the third zone, and a plurality of gas supply holes 234h are formed in side surfaces of the first reactive gas supply nozzle 234 in the fourth zone.

Similarly, the second reactive gas supply nozzle 331 is elongated to the upper portion of the first zone, the second reactive gas supply nozzle 332 is elongated to the upper portion of the second zone, the second reactive gas supply nozzle 333 is elongated to the upper portion of the third zone, and the second reactive gas supply nozzle 334 is elongated to the upper portion of the fourth zone. Also, a plurality of gas supply holes 331h are formed in side surfaces of the second reactive gas supply nozzle 331 in the first zone, a plurality of gas supply holes 332h are formed in side surfaces of the second reactive gas supply nozzle 332 in the second zone, a plurality of gas supply holes 333h are formed in side surfaces of the second reactive gas supply nozzle 333 in the third zone, and a plurality of gas supply holes 334h are formed in side surfaces of the second reactive gas supply nozzle 334 in the fourth zone. Also, for convenience of illustration, FIG. 1 illustrates the gas supply holes 231h and 331h, the gas supply holes 232h and 332h, the gas supply holes 233h and 333h, and the gas supply holes 234h and 334h, only at a side of each of these nozzles. Also, FIG. 2 illustrates only reference numerals 234h and 334h.

The gas supply holes 231h to 234h and 331h to 334h open toward a center of the reaction tube 203 to supply a gas toward the wafers 202. The gas supply holes 231h to 234h and 331h to 334h are formed from a lower portion of each of the first to fourth zones to an upper portion thereof and each have the same opening area at the same opening pitch. The gas supply holes 231h to 234h and 331h to 334h are preferably disposed between the wafers 202 to correspond to the wafers 202 stacked on the boat 217, and configured such that gases discharged from these gas supply holes flow in a horizontal direction between the wafers 202. By configuring these gas supply holes as described above, gases discharged from the gas supply holes in each of the first to fourth zones may be effectively suppressed from being mixed with gases discharged from the other zones.

The first reactive gas supply nozzle 231 is configured to supply a gas into the first zone, the first reactive gas supply nozzle 232 is configured to supply a gas into the second zone, the first reactive gas supply nozzle 233 is configured to supply a gas into the third zone, and the first reactive gas supply nozzle 234 is configured to supply a gas into the fourth zone. Each of the first reactive gas supply nozzles 231 to 234 is preferably configured not to supply a gas into the zones to which it does not belong. Similarly, the second reactive gas supply nozzle 331 is configured to supply a gas into the first zone, the second reactive gas supply nozzle 332 is configured to supply a gas into the second zone, the second reactive gas supply nozzle 333 is configured to supply a gas into the third zone, and the second reactive gas supply nozzle 334 is configured to supply a gas into the fourth zone. Each of the second reactive gas supply nozzles 331 to 334 is preferably configured not to supply a gas into the zones to which it does not belong.

As described above, in a gas supply method according to the present embodiment, a gas is transferred via the first reactive gas supply nozzles 231 to 234 and the second reactive gas supply nozzles 331 to 334 disposed in the arc-shaped space that is a vertically long space defined with the inner walls of the reaction tube 203 and end portions of the wafers 202, and first discharged into the reaction tube 203 near the wafers 202 from the gas supply holes 231h to 234h open in the first reactive gas supply nozzles 231 to 234 and the gas supply holes 331h to 334h open in the second reactive gas supply nozzles 331 to 334. Also, a main gas flow occurs in the reaction tube 203 in a direction parallel to surfaces of the wafers 202, i.e., a horizontal direction. Accordingly, a gas may be evenly supplied onto the wafers 202, thereby unifying the thicknesses of thin films formed on the respective wafers 202. Also, a residual gas that remains after a reaction flows toward exhaust holes 203c which will be described below is then exhausted from the exhaust pipe 271 via an exhaust chamber 201a.

As illustrated in FIG. 2, first reactive gas supply pipes 231a to 234a configured to supply the first reactive gas are connected to the first reactive gas supply nozzles 231 to 234, respectively, and second reactive gas supply pipes 331a to 334a configured to supply the second reactive gas are connected to the second reactive gas supply nozzles 331 to 334, respectively.

A TEMAZ source 241 that supplies the first reactive gas, a valve 261c which is an opening/closing valve, a mass flow controller (MFC) 251a which is a flow rate controller (flow rate control unit), and a valve 261a are sequentially installed at the first reactive gas supply pipe 231a in an upstream direction. Also, an inert gas supply pipe 231b is connected to the first reactive gas supply pipe 231a at a downstream side of the valve 261a. At the inert gas supply pipe 231b, a N₂ gas source 243 which is an inert gas source, a valve 261d, an MFC 251b, and a valve 261b are sequentially installed in the upstream direction. The first reactive gas supply nozzle 231 is connected to a front end portion (lowermost downstream side) of the first reactive gas supply pipe 231a, and configured to supply the first reactive gas into the first zone.

Similarly, the TEMAZ source 241, a valve 262c, an MFC 252a, and a valve 262a are sequentially installed at the first reactive gas supply pipe 232a in the upstream direction. Also, an inert gas supply pipe 232b is connected to the first reactive gas supply pipe 232a at a downstream side of the valve 262a. The N₂ gas source 243, a valve 262d, an MFC 252b, and a valve 262b are sequentially installed at the inert gas supply pipe 232b in the upstream direction. The first reactive gas supply nozzle 232 is connected to a front end portion (lowermost downstream side) of the first reactive gas supply pipe 232a, and configured to supply the first reactive gas into the second zone.

Similarly, the TEMAZ source 241, a valve 263c, an MFC 253a, and a valve 263a are installed at the first reactive gas supply pipe 233a in the upstream direction. Also, an inert gas supply pipe 233b is connected to the first reactive gas supply pipe 233a at a downstream side of the valve 263a. The N₂ gas source 243, a valve 263d, an MFC 253b, and a valve 263b are sequentially installed at the inert gas supply pipe 233b in the upstream direction. The first reactive gas supply nozzle 233 is connected to a front end portion (lowermost downstream side) of the first reactive gas supply pipe 233a, and configured to supply the first reactive gas into the third zone.

Similarly, the TEMAZ source 241, a valve 264c, an MFC 254a, and a valve 264a are sequentially installed at the first reactive gas supply pipe 234a in the upstream direction. Also, an inert gas supply pipe 234b is connected to the first reactive gas supply pipe 234a at a downstream side of the valve 264a. The N₂ gas source 243, a valve 264d, an MFC 254b, and a valve 264b are sequentially installed at the inert gas supply pipe 234b in the upstream direction. The first reactive gas supply nozzle 234 is connected to a front end portion (lowermost downstream side) of the first reactive gas supply pipe 234a, and configured to supply the first reactive gas into the fourth zone.

The first reactive gas supply system mainly includes the first reactive gas supply pipes 231a to 234a, the valves 261c to 264c, the MFCs 251a to 254a, and the valves 261a to 264a. The first reactive gas supply system may further include the TEMAZ source 241 which is a first reactive gas source, the first reactive gas supply nozzles 231 to 234, or the gas supply holes 231h to 234h. The first inert gas supply system mainly includes the inert gas supply pipes 231b to 234b, the valves 261d to 264d, the MFCs 251b to 254b, and the valves 261b to 264b. The first inert gas supply system also acts as a first purge gas supply system. The first inert gas supply system may further include the N₂ gas source 243 which is an inert gas source, the first reactive gas supply nozzles 231 to 234, or the gas supply holes 231h to 234h.

Tetrakis(ethylmethylamino)zirconium (Zr[N(C₂H₅)(CH₃)]₄; TEMAZ) gas is supplied as a source gas containing zirconium (Zr) which is a metal element (zirconium source gas) into the process chamber 201 from the first reactive gas supply pipes 231a to 234a via the valves 261c to 264c, the MFCs 251a to 254a, the valves 261a to 264a, and the first reactive gas supply nozzles 231 to 234. That is, the first reactive gas supply system is configured as a zirconium source gas supply system. At this time, an inert gas may be supplied into the first reactive gas supply pipes 231a to 234a from the inert gas supply pipes 231b to 234b via the valves 261d to 264d, the MFCs 251b to 254b, and the valves 261b to 264b. The inert gas supplied into the first reactive gas supply pipes 231a to 234a is supplied into the process chamber 201 together with the TEMAZ gas via the first reactive gas supply nozzles 231 to 234. When a liquid source, such as the TEMAZ gas, which is in a liquid state at normal temperature and pressure is used, the liquid source is vaporized using a vaporization system such as a vaporizer or a bubbler and is supplied as a source gas.

An O₃ source 242 which is a second reactive gas source, a valve 361c, an MFC 351a, and a valve 361a are sequentially installed at the second reactive gas supply pipe 331a in the upstream direction. Also, an inert gas supply pipe 331b is connected to the second reactive gas supply pipe 331a at a downstream side of the valve 361a. The N₂ gas source 243 which is an inert gas source, a valve 361d, an MFC 351b, and a valve 361b are sequentially installed at the inert gas supply pipe 331b in the upstream direction. The second reactive gas supply nozzle 331 is connected to a front end portion (lowermost downstream side) of the second reactive gas supply pipe 331a, and configured to supply the second reactive gas into the first zone.

Similarly, the O₃ source 242, a valve 362c, an MFC 352a, and a valve 362a are sequentially installed at the second reactive gas supply pipe 332a in the upstream direction. An inert gas supply pipe 332b is connected to the second reactive gas supply pipe 332a at a downstream side of the valve 362a. The N₂ gas source 243 which is an inert gas source, a valve 362d, an MFC 352b, and a valve 362b are sequentially installed at the inert gas supply pipe 332b in the upstream direction. The second reactive gas supply nozzle 332 is connected to a front end portion (lowermost downstream side) of the second reactive gas supply pipe 332a, and configured to supply the second reactive gas into the second zone.

Similarly, the O₃ source 242, a valve 363c, an MFC 353a, and a valve 363a are sequentially installed at the second reactive gas supply pipe 333a in the upstream direction. Also, an inert gas supply pipe 333b is connected to the second reactive gas supply pipe 333a at a downstream side of the valve 363a. The N₂ gas source 243 which is an inert gas source, a valve 363d, an MFC 353b, and a valve 363b are sequentially installed at the inert gas supply pipe 333b in the upstream direction. The second reactive gas supply nozzle 333 is connected to a front end portion (lowermost downstream side) of the second reactive gas supply pipe 333a, and configured to supply the second reactive gas into the third zone.

Similarly, the O₃ source 242, a valve 364c, an MFC 354a, and a valve 364a are sequentially installed at the second reactive gas supply pipe 334a in the upstream direction. An inert gas supply pipe 334b is connected to the second reactive gas supply pipe 334a at a downstream side of the valve 364a. The N₂ gas source 243 which is an inert gas source, a valve 364d, an MFC 354b, and a valve 364b are sequentially installed at the inert gas supply pipe 334b. The second reactive gas supply nozzle 334 is connected to a front end portion (lowermost downstream side) of the second reactive gas supply pipe 334a, and configured to supply the second reactive gas into the fourth zone.

The second reactive gas supply system mainly includes the second reactive gas supply pipes 331a to 334a, the valves 361c to 364c, the MFCs 351a to 354a, and the valves 361a to 364a. The second reactive gas supply system may further include the second reactive gas source 242, the second reactive gas supply nozzles 331 to 334, or the gas supply holes 331h to 334h. The second inert gas supply system mainly includes the inert gas supply pipes 331b to 334b, the valves 361d to 364d, the MFCs 351b to 354b, and the valves 361b to 364b. The second inert gas supply system also acts as a second purge gas supply system. The second inert gas supply system may further include the inert gas source 243, the second reactive gas supply nozzles 331 to 334, or the gas supply holes 331h to 334h.

Ozone (O₃) gas which is the second reactive gas is supplied as an oxidizing gas into the process chamber 201 from the second reactive gas supply pipes 331a to 334a via the valves 361c to 364c, the MFCs 351a to 354a, the valves 361a to 364a, and the second reactive gas supply nozzles 331 to 334. That is, the second reactive gas supply system is configured as an ozone gas supply system that supplies ozone gas which is an oxidizing gas. At the same time, an inert gas may be supplied into the second reactive gas supply pipes 331a to 334a from the inert gas supply pipes 331b to 334b via the valves 361d to 364d, the MFCs 351b to 354b, and the valves 361b to 364b. The inert gas supplied into the second reactive gas supply pipes 331a to 334a may be supplied together with the O₃ gas into the process chamber 201 via the second reactive gas supply nozzles 331 to 334.

Next, a gas exhaust system will be described. As illustrated in FIG. 1, the plurality of exhaust holes 203c are formed in a reaction tube sidewall 203b of the reaction tube 203 facing the reactive gas supply nozzles 231 to 234 and 331 to 334 to discharge an atmosphere in the process chamber 201. In the present embodiment, the exhaust holes 203c each have a horizontally long slit shape, and are formed at positions facing the gas supply holes 231h to 234h (or the gas supply holes 331h to 334h). The height of the exhaust holes 203c is the same as that of the gas supply holes 231h to 234h (or the gas supply holes 331h to 334h), and the number of the exhaust holes 203c is equal to the number of the gas supply holes 231h to 234h (or the gas supply holes 331h to 334h).

The exhaust chamber 201a is installed at outer sides of the exhaust holes 203c. The exhaust chamber 201a is formed as an inside (hollow portion) of a long cylinder in a vertical direction. The cylinder is configured by an exhaust chamber sidewall 203a and the reaction tube sidewall 203b. An upper end of the exhaust chamber 201a is closed and a lower end of the exhaust chamber 201a is connected to the exhaust pipe 271. By installing the exhaust chamber 201a, gases discharged into the process chamber 201 in a horizontal direction from the gas supply holes 231h to 234h or the gas supply holes 331h to 334h are likely to flow in the process chamber 201 toward the exhaust holes 203c.

Also, partition plates 203d are installed on inner walls of the reaction tube 203 at the boundaries between the first to fourth zones to protrude inwardly from the inner walls of the reaction tube 203. The partition plates 203d are welded on the inner walls of the reaction tube 203. As illustrated in FIG. 2, the partition plates 203d each have a top surface having a ring shape (donut shape), and suppress a gas, which is discharged into the process chamber 201 in a horizontal direction from the gas supply holes in each of the first to fourth zones, from being mixed with gases discharged from the other zones. The exhaust chamber sidewall 203a and the partition plates 203d are formed of a material such as quartz, similar to the reaction tube 203.

The exhaust pipe 271 is connected to a lower portion of the reaction tube 203, i.e., a lower portion of the exhaust chamber 201a, to exhaust an atmosphere in the exhaust chamber 201a. An exhaust port is formed at a junction of the exhaust chamber 201a and the exhaust pipe 271. A pressure sensor 274 serving as a pressure detector (pressure detection unit) configured to detect pressure in the process chamber 201 is connected to the exhaust pipe 271. Also, a vacuum pump 273 serving as a vacuum exhaust device is connected to the exhaust pipe 271 via an auto pressure controller (APC) valve 272 serving a pressure adjustor (pressure adjustment unit). Also, the APC valve 272 may be configured to vacuum-exhaust the inside of the process chamber 201 or suspend the vacuum-exhausting by opening/closing the APC valve 272 while the vacuum pump 273 is operated, and to adjust pressure in the process chamber 201 by adjusting a degree of opening of the APC valve 272 while the vacuum pump 273 is operated. An exhaust system mainly includes the exhaust holes 203c, the exhaust chamber 201a, the exhaust pipe 271, the pressure sensor 274, and the APC valve 272. The exhaust system may further include the vacuum pump 273.

During processing of the wafers 202, the pressure in the process chamber 201 is adjusted (controlled) to a predetermined pressure (degree of vacuum) that is less than atmospheric pressure by adjusting the degree of opening of the APC valve 272 based on pressure information detected by the pressure sensor 274 while the vacuum pump 273 is operated. A pressure control unit (pressure adjustment unit) is mainly configured by the pressure sensor 274 and the APC valve 272.

Below the reaction tube 203, a seal cap 219 is installed as a furnace port lid that may air-tightly close a lower end aperture of the reaction tube 203. The seal cap 219 is configured to come in contact with a lower end of the reaction tube 203 from a lower portion thereof in a vertical direction. The seal cap 219 is formed of, for example, a metal such as stainless steel and has a disk shape. An O-ring 220 serving as a seal member that comes in contact with the lower end of the reaction tube 203 is installed on an upper surface of the seal cap 219. A boat rotating mechanism 267 that rotates the boat 217 as a substrate retainer (which will be described below) is installed at a side of the seal cap 219 opposite to the process chamber 201. A rotation shaft 265 of the boat rotating mechanism 267 is connected to the boat 217 while passing through the seal cap 219. The boat rotating mechanism 267 is configured to rotate the wafers 202 by rotating the boat 217.

The seal cap 219 is configured to be vertically moved by a boat elevator 115 that is a lifting mechanism vertically installed outside the reaction tube 203. The boat elevator 115 is configured to load the boat 217 into or unload the boat 217 from the process chamber 201 by moving the seal cap 219 upward/downward. That is, the boat elevator 115 is configured as a transfer device (transfer mechanism) that transfers the boat 217, i.e., the wafers 202, into or out of the process chamber 201.

The boat 217 serving as a substrate retainer is formed of a heat-resistant material, e.g., quartz or silicon carbide, and is configured to retain the wafers 202 in a state in which the wafers 202 are arranged in a concentrically multilayered structure in a horizontal posture. An insulating member 218 formed of a heat-resistant material, e.g., quartz or silicon carbide, is installed below the boat 217, and configured to prevent heat generated from the heater 207 from being transferred to the seal cap 219. Also, the insulating member 218 may include a plurality of insulating plates formed of a heat-resistant material, e.g., quartz or silicon carbide, and an insulating plate holder that supports the plurality of insulating plates in a multilayered structure in a horizontal posture.

As illustrated in FIG. 2, temperature sensors 208 are installed as temperature detectors in the reaction tube 203. The temperature sensors 208 are installed in the first to fourth zones, respectively and configured to control an amount of current to be supplied to the first to fourth zone heaters 2071 to 2074 based on temperature information detected by the temperature sensors 208 in the first to fourth zones, so that the process chamber 201 may have a desired temperature distribution. The temperature sensors 208 have an L shape similar to the first reactive gas supply nozzles 231 to 234 or the second reactive gas supply nozzles 331 to 334, and are installed along an inner wall of the reaction tube 203. During processing of the wafers 202, the wafers 202 in the process chamber 201 are controlled to have a predetermined temperature by controlling the amount of current to be supplied to the heater 207 (the first to fourth zone heaters 2071 to 2074) based on the temperature information detected by the temperature sensors 208.

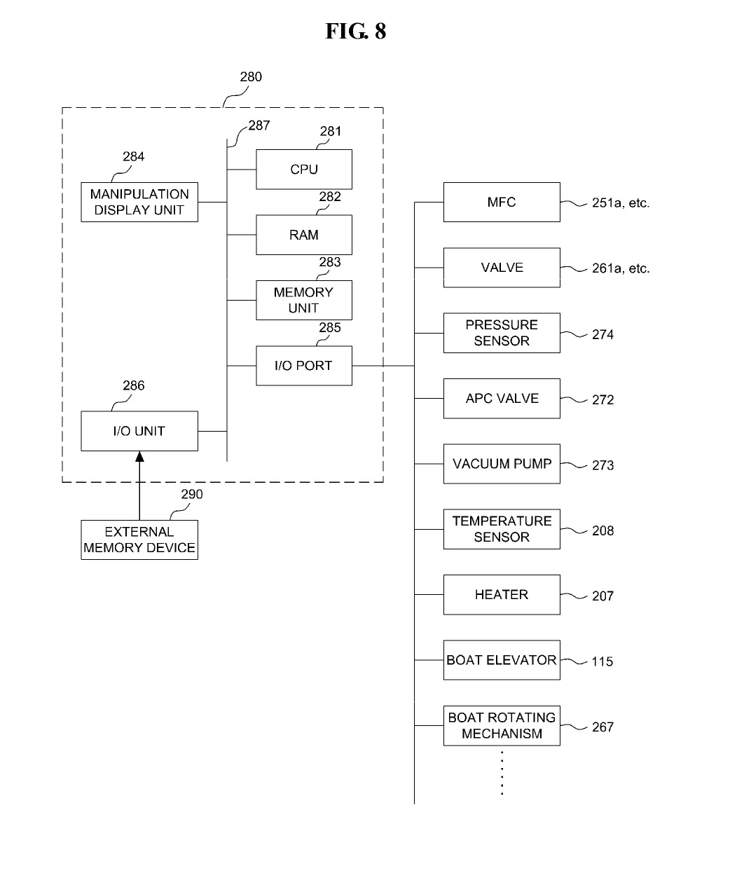

Next, the control unit 280 will be described with reference to FIG. 8. FIG. 8 is a block diagram of the control unit 280 according to an embodiment of the present invention. As illustrated in FIG. 8, the controller 280, which is a control unit (control means), is configured as a computer that includes a central processing unit (CPU) 281, a random access memory (RAM) 282, a memory unit 283, a manipulation display unit 284, an input/output (I/O) port 285, and an I/O unit 286. The RAM 282, the memory unit 283, the manipulation display unit 284, the I/O port 285, and the I/O unit 286 are configured to exchange data with the CPU 281 via an internal bus 287. The manipulation display unit 284 is used to receive an input such as an instruction from a manipulator and to display various data thereon, and is configured by, for example, a touch panel.

The memory unit (memory device) 283 is configured, for example, as a flash memory, a hard disk drive (HDD), or the like. In the memory unit 283, either a control program for controlling an operation of a substrate processing apparatus or a process recipe including an order or conditions of substrate processing which will be described below is stored to be readable. Also, the process recipe is a combination of sequences of a substrate processing process which will be described below to obtain a desired result when the sequences are performed by the controller 280, and acts as a program. Hereinafter, the process recipe, the control program, etc. will also be referred to together simply as a ‘program.’ Also, when the term ‘program’ is used in the present disclosure, it should be understood as including only a process recipe, only a control program, or both of the process recipe and the control program. The RAM 282 is configured as a work area in which a program or data read by the CPU 281 is temporarily stored.

The I/O port 285 is connected to various elements of the substrate processing apparatus, such as the MFCs 251a to 254a, 251b to 254b, 351a to 354a, and 351b to 354b, the opening/closing valves 261a to 264a, 261b to 264b, 261c to 264c, 261d to 264d, 361a to 364a, 361b to 364b, 361c to 364c, and 361d to 364d, the pressure sensor 274, the APC valve 272, the vacuum pump 273, the temperature sensor 208, the heater 207, the boat elevator 115, the boat rotating mechanism 267, etc. The I/O port 285 not only transmits sensor information received from the various elements, etc. to the CPU 281 but also transmits instructions related to the various elements, which are received from the CPU 281, to the various elements. The I/O unit 286 performs an input/output operation of reading a program or various data from an external memory device 290 (which will be described below) installed outside the controller 280, writing the program or various data to the memory unit 283, reading a program or various data stored in the memory unit 283, and writing the program or various data to the external memory device 290.

The CPU 281 is configured to read and execute a control program from the memory unit 283, and to read a process recipe from the memory unit 283 according to a manipulation command input via the manipulation display unit 284. Also, according to the read process recipe, the CPU 281 is configured to control flow rates of various gases via the MFCs 251a to 254a, 251b to 254b, 351a to 354a, and 351b to 354b; control opening/closing of the valves 261a to 264a, 261b to 264b, 261c to 264c, 261d to 264d, 361a to 364a, 361b to 364b, 361c to 364c, and 361d to 364d; control opening/closing of the APC valve 272; control the degree of pressure using the APC valve 272 based on the pressure sensor 274; control temperature using the heater 207 based on the temperature sensor 208; control driving/suspending of the vacuum pump 273; control upward/downward movement of the boat 217 using the boat elevator 115; control the rotation and rotation speed of the boat 217 using the boat rotating mechanism 267; and so on, via the I/O port 285.

The controller 280 is not limited to a dedicated computer and may be configured as a general-purpose computer. For example, the controller 280 according to the present embodiment may be configured by preparing the external memory device 290 which is a computer-readable memory device storing a program as described above [e.g., a magnetic disk (a magnetic tape, a flexible disk, a hard disk, etc.), an optical disc (a compact disc (CD), a digital versatile disc (DVD), etc.), a magneto-optical (MO) disc, or a semiconductor memory (a Universal Serial Bus (USB) memory, a memory card, etc.)], and then installing the program in a general-purpose computer using the external memory device 290 via the I/O unit 286. Also, means for supplying a program to a computer are not limited to using the external memory device 290. For example, a program may be supplied to a computer using communication means, e.g., the Internet or an exclusive line, without using the external memory device 290. The memory unit 283 or the external memory device 290 may be configured as a non-transitory computer-readable recording medium. Hereinafter, the memory unit 283 or the external memory device 290 may also be referred to together simply as a ‘recording medium.’ Also, when the term ‘recording medium’ is used in the present disclosure, it may be understood as only the memory unit 283, only the external memory device 290, or both the memory unit 283 and the external memory device 290.

Next, an example of a thin film forming sequence of forming a metal oxide film as an oxide film (which is a high dielectric constant insulating film) on a substrate using the process furnace 200 of the substrate processing apparatus described above will be described as a process included in a process of manufacturing a semiconductor device (device). In the present embodiment, the thin film forming sequence will be described using a case in which Zr[N(C₂H₅)(CH₃)]₄ (TEMAZ) is used as a Zr precursor and O₃ is used as an oxidizing source when a ZrO₂ film is formed as an insulating film. Also, in the following description, operations of various elements of the substrate processing apparatus are controlled by the controller 280.

First, when a plurality of wafers 202 are loaded in the boat 217 (wafer charging), the boat 217 retaining the plurality of wafers 202 is lifted by the boat elevator 115 and loaded into the process chamber 201 (boat loading), as illustrated in FIG. 1. In this state, the lower end of the reaction tube 203 is air-tightly closed by the seal cap 219 via the O-ring 220.

Then, the inside of the process chamber 201 is vacuum-exhausted to have a desired pressure (degree of vacuum) that is lower than atmospheric pressure by the vacuum pump 273. In this case, the pressure in the process chamber 201 is measured by the pressure sensor 274, and the APC valve 272 is feedback-controlled based on information regarding the measured pressure (pressure control). Also, the vacuum pump 273 is kept operated at least until processing of the wafers 202 is completed.

Also, the wafers 202 in the process chamber 201 are heated to a desired temperature by the heater 207 (the six zone heaters 2071 to 2076). In this case, an amount of current supplied to the heater 207 is feedback-controlled based on temperature information detected by the temperature sensor 208, so that the inside of the process chamber 201 may have a desired temperature distribution (temperature control). The heating of the wafers 202 in the process chamber 201 by the heater 207 is continuously performed at least until the processing of the wafers 202 is completed.

Then, rotation of the boat 217 and the wafers 202 begins by the boat rotating mechanism 267. Also, the rotation of the boat 217 and the wafers 202 by the boat rotating mechanism 267 is continuously performed at least until the processing of the wafers 202 is completed.

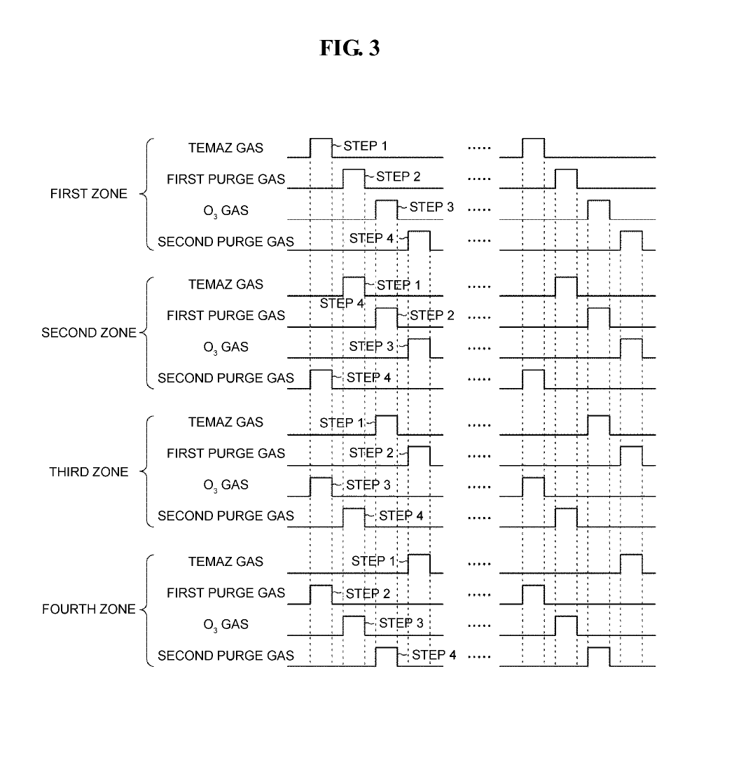

After the rotation of the boat 217 begins, a thin film is formed by sequentially performing four steps which will be described below. That is, a process of forming a thin film according to the present embodiment consists of the four steps (element processes). A timing chart of the four steps is illustrated in FIG. 3. FIG. 3 is a gas supply timing chart of a film-forming sequence according to the present embodiment. For convenience of explanation, FIG. 3 illustrates a timing of supplying main materials into a process chamber.

When the term ‘wafer’ is used in the present disclosure, it should be understood as either the wafer itself or a stacked structure (assembly) including the wafer and a layer/film formed on the wafer (i.e., the wafer and the layer/film formed thereon may also be referred to collectively as the ‘wafer’). Also, when the expression ‘surface of the wafer’ is used in the present disclosure, it should be understood as either a surface (exposed surface) of the wafer itself or a surface of a layer/film formed on the wafer, i.e., an uppermost surface of the wafer as a stacked structure.

Thus, in the present disclosure, the expression ‘specific gas is supplied onto a wafer’ should be understood to mean that the specific gas is directly supplied onto a surface (exposed surface) of the wafer or that the specific gas is supplied onto a surface of a layer/film on the wafer, i.e., onto the uppermost surface of the wafer as a stacked structure. Also, in the present disclosure, the expression ‘a layer (or film) is formed on the wafer’ should be understood to mean that the layer (or film) is directly formed on a surface (exposed surface) of the wafer itself or that the layer (or film) is formed on the layer/film on the wafer, i.e., on the uppermost surface of the wafer as a stacked structure.

Also, in the present disclosure, the term ‘substrate’ has the same meaning as the term ‘wafer.’ Thus, the term ‘wafer’ may be used interchangeably with the term ‘substrate.’

First, steps 1 to 4 to be performed in the first zone will be described below.

### [Step 1] (Process of Forming a Zirconium-Containing Layer)

In step 1, TEMAZ gas is supplied into the first zone as illustrated in FIG. 3. Specifically, the valves 261c and 261a of the first reactive gas supply pipe 231a are opened to supply the TEMAZ gas into the first reactive gas supply pipe 231a. The flow rate of the TEMAZ gas is adjusted by the MFC 251a. The flow rate controlled TEMAZ gas is supplied to be discharged in a horizontal direction into the first zone which is a wafer arrangement region of the process chamber 201 (which is heated to a predetermined temperature and has a reduced-pressure state) from the plurality of gas supply holes 231h of the first reactive gas supply nozzle 231. The TEMAZ gas supplied into the first zone flows in the first zone in the horizontal direction, is discharged into the exhaust chamber 201a from the exhaust holes (slits) 203c installed to face the plurality of gas supply holes 231h, flows down in the exhaust chamber 201a, and is then exhausted from the exhaust pipe 271 via the exhaust port installed at the lower end of the reaction tube 203. In this case, the TEMAZ gas is supplied onto the wafers 202 in the first zone.

In this case, N₂ gas, which is an inert gas, may be supplied as a carrier gas from the inert gas supply pipe 231b by opening the valves 261d and 261b of the inert gas supply pipe 231b. The flow rate of the N₂ gas is adjusted by the MFC 251b, and the flow rate adjusted N₂ gas is supplied into the first reactive gas supply pipe 231a. The flow rate adjusted N₂ gas is mixed with the TEMAZ gas, the flow rate of which is adjusted in the first reactive gas supply pipe 231a. The mixture gas of the N₂ gas and the TEMAZ gas is supplied into the first zone from the gas supply holes 231h of the first reactive gas supply nozzle 231, and exhausted from the exhaust pipe 271 via the exhaust chamber 201a. Also, in this case, the valves 361d and 361b of the inert gas supply pipe 331b are opened to supply N₂ gas into the second reactive gas supply pipe 331a from the inert gas supply pipe 331b in order to prevent the TEMAZ gas from flowing into the second reactive gas supply nozzle 331. The N₂ gas supplied into the second reactive gas supply pipe 331a flows into the process chamber 201 from the gas supply holes 331h of the second reactive gas supply nozzle 331. Thus, the TEMAZ gas supplied into the process chamber 201 may be prevented from flowing into the second reactive gas supply nozzle 331.

In step 1, the pressure in the process chamber 201 is kept to be lower than atmospheric pressure, e.g., a pressure that is, for example, within a range of 1 to 1,333 Pa, by appropriately controlling the APC valve 272. The supply flow rate of the TEMAZ gas controlled by the MFC 251a is set, for example, to be within 1 to 2,000 sccm (a range of 0.01 slm to 2 slm). The supply flow rates of the N₂ gas controlled by the MFCs 251b and 351b are set, for example, to be within a range of 200 sccm to 10,000 sccm (a range of 0.2 slm to 10 slm). A duration for which the TEMAZ gas is supplied onto the wafers 202 is set to range, for example, from 1 to 120 seconds. A temperature of the heater 207 is set such that a chemical vapor deposition (CVD) reaction occurs in the process chamber 201 in the range of pressure described above. That is, the temperature of the heater 207 is set such that the wafers 202 have a predetermined temperature, e.g., a temperature that is within a range of 100° C. to 400° C. When the temperature of the wafers 202 is less than 100° C., the TEMAZ gas is not easily decomposed on or adsorbed onto the wafer 202. When the temperature of the wafers 202 is greater than 400° C., the CVD reaction becomes stronger, thereby greatly degrading film thickness uniformity in a plane on the wafers 202. Thus, the temperature of the wafers 202 is preferably set to be within a range of 100° C. to 400° C.

By supplying the TEMAZ gas into the first zone under the above-described conditions, i.e., conditions that cause the CVD reaction to occur, a zirconium-containing layer is formed on the wafers 202 (on base films formed on the wafers 202) in the first zone to a thickness of, for example, less than one atomic layer to several atomic layers. The zirconium-containing layer may be a zirconium layer (Zr layer), an adsorption layer of TEMAZ gas, or both of these layers.

Here, a layer having a thickness of less than one atomic layer means an atomic layer discontinuously formed in a direction of a plane of the wafer 202 (a direction of a surface of the wafer 202). A layer having a thickness of one atomic layer means an atomic layer continuously formed in the direction of the plane of the wafer 202. Also, a layer having a thickness of less than one molecular layer which will be described below means a molecular layer discontinuously formed in the direction of the plane of the wafer 202, and a layer having a thickness of one molecular layer means a molecular layer continuously formed in the direction of the plane of the wafer 202.

The zirconium layer described above is a generic term including a layer continuously formed of zirconium (Zr) in the direction of the plane of the wafer 202, and a zirconium thin film obtained by overlapping such layers. The layer continuously formed of zirconium (Zr) in the direction of the plane of the wafer 202 may also be referred to as a ‘zirconium thin film.’ Also, zirconium (Zr) used to form the zirconium layer should be understood as including zirconium (Zr) from which bonds with at least some atoms that form ligands in TEMAZ is not completely broken. Examples of the adsorption layer of TEMAZ gas include not only a chemical adsorption layer including continuous gas molecules of the TEMAZ gas in the direction of the plane of the wafer 202 but also chemical adsorption layers including discontinuous gas molecules of the TEMAZ gas in the direction of the plane of the wafer 202. That is, the adsorption layer of the TEMAZ gas includes a chemical adsorption layer formed of TEMAZ molecules to a thickness of one molecular layer or less than one molecular layer. Also, TEMAZ molecules of the adsorption layer of the TEMAZ gas should be understood as including TEMAZ molecules from which bonds between zirconium (Zr) and ligands is partially broken or from which at least some elements of the ligands are separated.

Zirconium (Zr) is deposited on the wafer 202 to form a zirconium (Zr) layer under conditions in which TEMAZ gas is self-decomposed (pyrolyzed), i.e., conditions causing a pyrolysis reaction of the TEMAZ gas. The TEMAZ gas is adsorbed onto the wafer 202 to form an adsorption layer of the TEMAZ gas under conditions in which the TEMAZ gas is not self-decomposed (pyrolyzed), i.e., conditions that do not cause a pyrolysis reaction of the TEMAZ gas. A film-forming rate may be higher when the zirconium (Zr) layer is formed on the wafer 202 than when the adsorption layer of the TEMAZ gas is formed on the wafer 202.

If the thickness of the zirconium-containing layer formed on the wafer 202 exceeds a thickness of several atomic layers, an oxidizing action to be performed in step 3 which will be described below does not have an effect on the entire zirconium-containing layer. The zirconium-containing layer that may be formed on the wafer 202 may have a minimum thickness of less than one atomic layer. Thus, the zirconium-containing layer may be set to have a thickness of less than one atomic layer to several atomic layers. Also, the oxidizing action performed in step 3 which will be described below may be relatively increased and a time required to perform the oxidizing action to be performed in step 3 may be reduced by controlling the zirconium-containing layer to have a thickness not more than one atomic layer, i.e., a thickness of less than one atomic layer or of one atomic layer. Also, a time required to form a zirconium-containing layer in step 1 may be reduced. Accordingly, a process time per cycle may be reduced and a total process time may be thus reduced. That is, a film-forming rate may be increased. Also, the controllability of film thickness uniformity may be increased by controlling the zirconium-containing layer to have a thickness of one atomic layer or less.

### [Step 2] (First Purge Process)

After the zirconium-containing layer is formed on the wafer 202, the valves 261c and 261a of the first reactive gas supply pipe 231a are closed to suspend the supply of the TEMAZ gas. In this case, the inside of the first zone is vacuum-exhausted by the vacuum pump 273 and a residual TEMAZ gas is discharged from the first zone by appropriately controlling the APC valve 272 in a state in which the APC valve 272 of the exhaust pipe 271 is open. In this case, while the valves 261d, 261b, 361d, and 361b are open, N₂ gas is supplied as an inert gas to be discharged into the first zone in a horizontal direction from the gas supply holes 231h of the first reactive gas supply nozzle 231 via the inert gas supply pipe 231b and the first reactive gas supply pipe 231a, and from the gas supply holes 331h of the second reactive gas supply nozzle 331 via the inert gas supply pipe 331b and the second reactive gas supply pipe 331a.

The N₂ gas supplied into the first zone horizontally flows in the first zone while pushing out a residual gas in the first zone, is discharged into the exhaust chamber 201a via the exhaust holes (slits) 203c in the first zone, flows down in the exhaust chamber 201a, and is then exhausted from the exhaust pipe 271 via the exhaust port installed at the lower end of the reaction tube 203. The N₂ gas acts as a purge gas for exhausting the remnant TEMAZ gas, and enables the TEMAZ gas remaining in the first zone to be effectively excluded from the first zone.

In this case, the remnant gas remaining in the first zone need not be completely excluded, and the inside of the first zone need not be completely purged. When a small amount of a gas remains in the first zone, step 3 that is to be performed thereafter will not be badly influenced by the gas. In this case, the flow rate of the N₂ gas to be supplied into the first zone need not be high. For example, the inside of the first zone may be purged without causing step 3 to be badly influenced by the gas by supplying an amount of the gas corresponding to the capacity of the first zone. As described above, when the inside of the first zone is not completely purged, a purge time may be reduced to improve the throughput. Furthermore, the consumption of the N₂ gas may be suppressed to a necessary minimum level.

In step 2, the temperature of the heater 207 is set to be within a range of 100° C. to 400° C., similar to that in step 1. The pressure in the process chamber 201 is kept to be equal to the pressure in the process chamber 201 in step 1, e.g., a pressure that is within a range of 1 Pa to 1,333 Pa, by appropriately controlling the APC valve 272. The supply flow rate of the N₂ gas serving as a purge gas is controlled by the MFCs 251b and 351b to be, for example, within a range of 200 sccm to 10,000 sccm (0.2 slm to 10 slm). A purge time is set to be equal to the process time in step 1, e.g., to be within a range of 1 to 120 seconds.

### [Step 3] (Oxidizing Process)

After the remnant gas in the first zone is removed, the valves 361c and 361a of the second reactive gas supply pipe 331a are opened to supply O₃ gas into the second reactive gas supply pipe 331a. The flow rate of the O₃ gas is adjusted by the MFC 351a. The flow rate adjusted O₃ gas is supplied into the first zone, which is heated to a predetermined temperature and has a reduced-pressure state, via the plurality of gas supply holes 331h of the second reactive gas supply nozzle 331. The O₃ gas supplied into the first zone flows in the first zone in a horizontal direction, is discharged into the exhaust chamber 201a from the exhaust holes (slits) 203c installed to correspond to the plurality of gas supply holes 331h, flows down in the exhaust chamber 201a, and is then exhausted from the exhaust pipe 271 via the exhaust port installed at the lower end of the reaction tube 203. In this case, the O₃ gas is supplied onto the wafers 202 in the first zone.

In this case, the valves 361d and 361b of the inert gas supply pipe 331b may be opened to supply N₂ gas (which is an inert gas) as a carrier gas from the inert gas supply pipe 331b. The flow rate of the N₂ gas is adjusted by the MFC 351b, and the flow rate adjusted N₂ gas is supplied into the second reactive gas supply pipe 331a. In this case, a mixture gas of the O₃ gas and the N₂ gas is supplied from the second reactive gas supply pipe 331a. Also, in this case, the valves 261d and 261b of the inert gas supply pipe 231b are opened to supply N₂ gas into the first reactive gas supply pipe 231a from the inert gas supply pipe 231b in order to prevent the O₃ gas from flowing into the first reactive gas supply nozzle 231. The N₂ gas supplied into the first reactive gas supply pipe 231a flows into the process chamber 201 from the gas supply holes 231h of the first reactive gas supply nozzle 231. Thus, the O₃ gas supplied into the process chamber 201 may be prevented from flowing into the first reactive gas supply nozzle 231.

In step 3, the pressure in the first zone, i.e., the pressure in the process chamber 201, is maintained to be the same as the pressure in step 1, e.g., a pressure that is within a range of 1 Pa to 1,333 Pa, by appropriately controlling the APC valve 272. The supply flow rate of the O₃ gas controlled by the MFC 351a is set to, for example, be within a range of 100 sccm to 10,000 sccm (a range of 0.1 slm to 10 slm). The supply flow rate of the N₂ gas adjusted by the MFCs 351b and 251b is set to, for example, be within a range of 200 sccm to 10,000 sccm (0.2 slm to 10 slm). A duration for which the O₃ gas is supplied onto the wafer 202 is set to be the same as the process time in step 1, for example, to be within a range of 1 to 120 seconds. A temperature of the heater 207 is set to be within the same range of temperature as in step 1, e.g., a range of 100° C. to 400° C.

By supplying the O₃ gas into the first zone under such conditions, the O₃ gas reacts with at least a portion of the zirconium-containing layer formed on the wafer 202. That is, the zirconium-containing layer is oxidized to be changed (modified) into a zirconium oxide layer (ZrO₂ layer, which may also be hereinafter referred to simply as a ZrO layer) through the oxidization.

### [Step 4] (Second Purge Process)

After the zirconium oxide layer is formed on the wafer 202 in step 3, i.e., after the zirconium-containing layer is changed into the zirconium oxide layer, the valves 361c and 361a of the second reactive gas supply pipe 331a are closed to suspend the supply of the O₃ gas. In this case, the inside of the first zone is vacuum-exhausted by the vacuum pump 273, and the remnant O₃ gas or byproducts are discharged from the inside of the first zone by appropriately controlling the APC valve 272 of the exhaust pipe 271 in a state in which the APC valve 272 is open. In this case, while the valves 361d, 361b, 261d, and 261b are open, N₂ gas is supplied as an inert gas to be discharged into the first zone in a horizontal direction from the gas supply holes 331h of the second reactive gas supply nozzle 331 via the inert gas supply pipe 331b and the second reactive gas supply pipe 331a, and from the gas supply holes 231h of the first reactive gas supply nozzle 231 via the inert gas supply pipe 231b and the first reactive gas supply pipe 231a.

The N₂ gas supplied into the first zone flows in the first zone in a horizontal direction while pushing out a remnant gas or byproducts in the first zone, is discharged into the exhaust chamber 201a via the exhaust holes (slits) 203c in the first zone, flows down in the exhaust chamber 201a, and is then exhausted from the exhaust pipe 271 via the exhaust port installed at the lower end of the reaction tube 203. The N₂ gas acts as a purge gas, and enables the O₃ gas or byproducts remaining in the first zone to be effectively excluded from the first zone.

Also, in this case, the gas remaining in the first zone need not be completely excluded and the inside of the first zone need not be completely purged. When a small amount of a gas remains in the first zone, step 1 performed thereafter will not be badly influenced by the gas. In this case, the flow rate of the N₂ gas to be supplied into the first zone need not be high. For example, the inside of the first zone may be purged without causing step 1 to be badly influenced by the gas by supplying an amount of the gas corresponding to the capacity of the first zone. As described above, when the inside of the first zone is not completely purged, a purge time may be reduced to improve the throughput. Furthermore, the consumption of the N₂ gas may be suppressed to a necessary minimum level.

In step 4, the temperature of the heater 207 is set to be the same as in step 1, e.g., to be within a range of 100° C. to 400° C. The pressure in the process chamber 201 is maintained to be the same as in step 1, e.g., to be within a range of 1 Pa 1,333 Pa, by appropriately controlling the APC valve 272. A supply flow rate of N₂ gas as a purge gas is adjusted by the MFCs 351b and 251b to be, for example, within a range of 200 sccm to 10,000 sccm (0.2 slm to 10 slm). A purge time is set to be the same as in step 1, e.g., to be within a range of 1 to 120 seconds.

As described above, in the present embodiment, in steps 1 to 4, the temperature of the heater 207 is set such that the wafer 202 may have a predetermined temperature, e.g., a constant temperature that is within a range of 100° C. to 400° C., and the APC valve 272 is controlled to set the pressure in the process chamber 201 to be the same as a predetermined pressure, e.g., a constant pressure that is within a range of 1 Pa to 1,333 Pa, so that the process time in each of steps 1 to 4 may be the same as a predetermined time, e.g., a time that is within a range of 1 to 120 seconds.

Alternatively, the process times in steps 1 to 4 may be equalized with a longest process time among the process times in steps 1 to 4. For example, when the process time in step 1 is longest, the process times in steps 2 to 4 are equalized with the process time in step 1. In this case, when the process time in step 3 is left, a sufficient amount of O₃ gas may be supplied, the supply of the O₃ gas may be stopped, and then only N₂ gas may be supplied during the left process time. When the process time in step 3 is longest, the process times in steps 1, 2, and 4 are equalized with the process time in step 3. In this case, when the process time in step 1 is left, a sufficient amount of TEMAZ gas may be supplied, the supply of the TEMAZ gas may be stopped, and only N₂ gas may be supplied during the left process time.

A zirconium oxide film (a ZrO₂ film, which may also be referred to simply as a ‘Zro film’) may be formed on the wafers 202 in the first zone to a predetermined thickness by repeatedly performing a cycle including steps 1 to 4 described above a predetermined number of times, and preferably a plurality of times. The thickness of the zirconium oxide film is set to, for example, be within a range of 8 nm to 20 nm.

Next, steps 1 to 4 performed in the second to fourth zones will be described. In the second to fourth zones, a zirconium oxide film is also formed on the wafers 202 to a predetermined thickness by repeatedly performing a cycle including steps 1 to 4 a predetermined number of times, and preferably a plurality of times, similar to in the first zone. In this case, as illustrated in FIG. 3, steps 1 to 4 are performed in each of the first to fourth zones as described above while retarding a timing of steps 1 to 4 by one step in the first to fourth zones.

Specifically, as illustrated in FIG. 3, first, the second purge process (step 4) is performed in the second zone, the process of supplying the second reactive gas (step 3) is performed in the third zone, and the first purge process (step 2) is performed in the fourth zone, at a timing when the process of supplying the first reactive gas (step 1) is performed in the first zone. Then, the process of supplying the first reactive gas (step 1) is performed in the second zone, the second purge process (step 4) is performed in the third zone, and the process of supplying the second reactive gas (step 3) is performed in the fourth zone, at a timing when the first purge process (step 2) is performed. Then, the first purge process (step 2) is performed in the second zone, the process of supplying the first reactive gas (step 1) is performed in the third zone, and the second purge process (step 4) is performed in the fourth zone, at a timing when the process of supplying the second reactive gas (step 3) is performed in the first zone. Then, the process of supplying the second reactive gas (step 3) is performed in the second zone, the first purge process (step 2) is performed in the third zone, and the process of supplying the first reactive gas (step 1) is performed in the fourth zone, at a timing when the second purge process (step 4) is performed in the first zone.

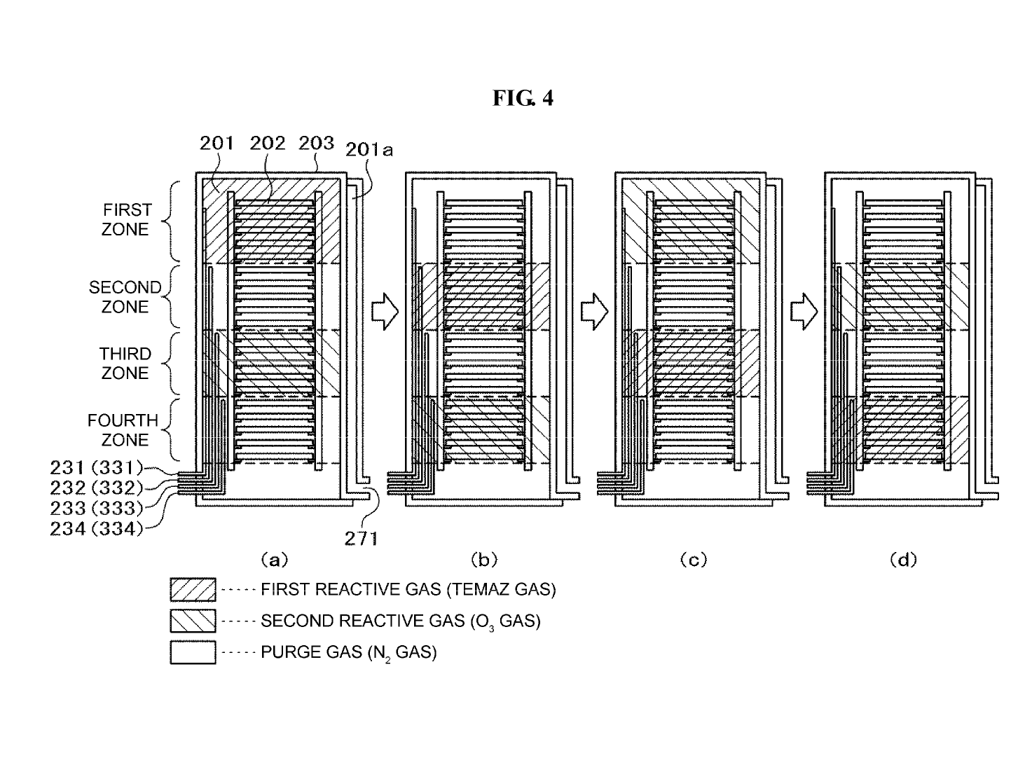

An atmosphere in a process furnace in a film-forming sequence according to the present embodiment is illustrated in FIG. 4. At a timing (a) of FIG. 4, the process of supplying the first reactive gas (step 1) is performed in the first zone, the second purge process (step 4) is performed in the second zone, the process of supplying the second reactive gas (step 3) is performed in the third zone, and the first purge process (step 2) is performed in the fourth zone. Next, at a timing (b) of FIG. 4 after one step is performed at the timing (a) of FIG. 4, the first purge process (step 2) is performed in the first zone, the process of supplying the first reactive gas (step 1) is performed in the second zone, the second purge process (step 4) is performed in the third zone, and the process of supplying the second reactive gas (step 3) is performed in the fourth zone. Next, at a timing (c) of FIG. 4 after one step is performed at the timing (b) of FIG. 4, the process of supplying the second reactive gas (step 3) is performed in the first zone, the first purge process (step 2) is performed in the second zone, the process of supplying the first reactive gas (step 1) is performed in the third zone, and the second purge process (step 4) is performed in the fourth zone. Next, at a timing (d) of FIG. 4 after one step is performed at the timing (c) of FIG. 4, the second purge process (step 4) is performed in the first zone, the process of supplying the second reactive gas (step 3) is performed in the second zone, the first purge process (step 2) is performed in the third zone, and the process of supplying the first reactive gas (step 1) is performed in the fourth zone.

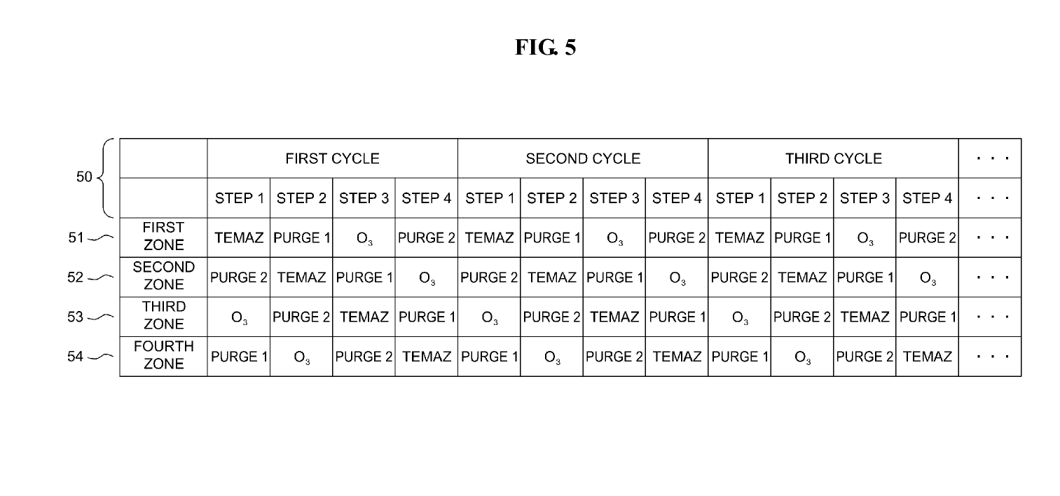

The film-forming sequence performed in each of the first to fourth zones in each of steps 1 to 4 described above is illustrated in FIG. 5. FIG. 5 is a table showing a film-forming sequence according to the present embodiment. In FIG. 5, a horizontal direction denotes a time flow (i.e., a process in each of the first to fourth zones) and a vertical direction denotes the first to fourth zones assigned reference numerals 51 to 54, respectively. Also, cycle numbers and step number ‘50’ are related to the first zone 51, and cycles numbers and step numbers related to the other zones are omitted herein. As illustrated in FIG. 5, for example, in a first cycle, a process of supplying a first reactive gas (TEMAZ) (step 1), a first purge process Purge1 (step 2), a process of supplying a second reactive gas (O₃) (step 3), and a second purge process Purge2 (step 4) are performed in the first zone 51. Then, a second cycle, a third cycle, etc. are performed similarly. Also, in a first cycle, the process of supplying the first reactive gas (TEMAZ) (step 1), the first purge process (step 2), the process of supplying a second reactive gas (O₃) (step 3), and the second purge process (step 4) are also performed in each of the second to fourth zones. Then, a second cycle, a third cycle, etc. are performed similarly.

Then, methods of supplying gases into the second to fourth zones will be described. In the second zone, in step 1, TEMAZ gas is supplied into the second zone from the gas supply holes 232h via the first reactive gas supply pipe 232a and the first reactive gas supply nozzle 232. In this case, N₂ gas may be supplied into the second zone from the gas supply holes 232h via the inert gas supply pipe 232b, the first reactive gas supply pipe 232a, and the first reactive gas supply nozzle 232. Also, in this case, N₂ gas is supplied into the second zone from the gas supply holes 332h via the inert gas supply pipe 332b, the second reactive gas supply pipe 332a, and the second reactive gas supply nozzle 332. Thus, the TEMAZ gas supplied into the process chamber 201 may be prevented from flowing into the second reactive gas supply nozzle 332.

Then, in step 2, N₂ gas which is a first purge gas is supplied into the second zone not only from the gas supply holes 232h via the inert gas supply pipe 232b, the first reactive gas supply pipe 232a, and the first reactive gas supply nozzle 232, but also from the gas supply holes 332h via the inert gas supply pipe 332b, the second reactive gas supply pipe 332a, and the second reactive gas supply nozzle 332.

Then, in step 3, O₃ gas is sequentially supplied into the second zone from the gas supply holes 332h via the second reactive gas supply pipe 332a and the second reactive gas supply nozzle 332. In this case, N₂ gas may also be supplied into the second zone from the gas supply holes 332h via the inert gas supply pipe 332b, the second reactive gas supply pipe 332a, and the second reactive gas supply nozzle 332. Also, N₂ gas is sequentially supplied into the second zone from the gas supply holes 232h via the inert gas supply pipe 232b, the first reactive gas supply pipe 232a, and the first reactive gas supply nozzle 232. Accordingly, the O₃ gas supplied into the process chamber 201 may be prevented from flowing into the first reactive gas supply nozzle 232.

Thereafter, in step 4, N₂ gas which is a second purge gas is supplied into the second zone not only from the gas supply holes 332h via the inert gas supply pipe 332b, the second reactive gas supply pipe 332a, and the second reactive gas supply nozzle 332, but also from the gas supply holes 232h via the inert gas supply pipe 232b, the first reactive gas supply pipe 232a, and the first reactive gas supply nozzle 232.

In the third zone, in step 1, TEMAZ gas is supplied into the third zone from the gas supply holes 233h via the first reactive gas supply pipe 233a, and the first reactive gas supply nozzle 233. In this case, N₂ gas may be supplied into the third zone from the gas supply holes 233h via the inert gas supply pipe 233b, the first reactive gas supply pipe 233a, and the first reactive gas supply nozzle 233. Also, in this case, N₂ gas is supplied into the third zone from the gas supply holes 333h via the inert gas supply pipe 333b, the second reactive gas supply pipe 333a, and the second reactive gas supply nozzle 333. Thus, the TEMAZ gas supplied into the process chamber 201 may be prevented from flowing into the second reactive gas supply nozzle 333.

Then, in step 2, N₂ gas which is a first purge gas is supplied into the third zone not only from the gas supply holes 233h via the inert gas supply pipe 233b, the first reactive gas supply pipe 233a, and the first reactive gas supply nozzle 233, but also from the gas supply holes 333h via the inert gas supply pipe 333b, the second reactive gas supply pipe 333a, and the second reactive gas supply nozzle 333.

Then, in step 3, O₃ gas is supplied into the third zone from the gas supply holes 333h via the second reactive gas supply pipe 333a, and the second reactive gas supply nozzle 333. In this case, N₂ gas may also be supplied into the third zone via the inert gas supply pipe 333b, the second reactive gas supply pipe 333a, the second reactive gas supply nozzle 333, and the gas supply holes 333h. Also, in this case, N₂ gas is supplied into the third zone from the gas supply holes 233h via the inert gas supply pipe 233b, the first reactive gas supply pipe 233a, and the first reactive gas supply nozzle 233. Accordingly, the O₃ gas supplied into the process chamber 201 may be prevented from flowing into the first reactive gas supply nozzle 233.

Next, in step 4, N₂ gas which is a second purge gas is supplied into the third zone not only from the gas supply holes 333h via the inert gas supply pipe 333b, the second reactive gas supply pipe 333a, and the second reactive gas supply nozzle 333, but also from the gas supply holes 233h via the inert gas supply pipe 233b, the first reactive gas supply pipe 233a, and the first reactive gas supply nozzle 233.

In the fourth zone, in step 1, TEMAZ gas is supplied into the fourth zone from the gas supply holes 234h via the first reactive gas supply pipe 234a, and the first reactive gas supply nozzle 234. In this case, N₂ gas may also be supplied into the fourth zone from the gas supply holes 234h via the inert gas supply pipe 234b, the first reactive gas supply pipe 234a, and the first reactive gas supply nozzle 234. Also, in this case, N₂ gas is supplied into the fourth zone from the gas supply holes 334h via the inert gas supply pipe 334b, the second reactive gas supply pipe 334a, and the second reactive gas supply nozzle 334. Thus, the TEMAZ gas supplied into the process chamber 201 may be prevented from flowing into the second reactive gas supply nozzle 334.

Then, in step 2, N₂ gas which is a first purge gas is supplied into the fourth zone not only from the gas supply holes 234h via the inert gas supply pipe 234b, the first reactive gas supply pipe 234a, and the first reactive gas supply nozzle 234, but also from the gas supply holes 334h via the inert gas supply pipe 334b, the second reactive gas supply pipe 334a, and the second reactive gas supply nozzle 334.

Then, in step 3, O₃ gas is supplied into the fourth zone from the gas supply holes 334h via the second reactive gas supply pipe 334a, and the second reactive gas supply nozzle 334. In this case, N₂ gas may also be supplied into the fourth zone from the gas supply holes 334h via the inert gas supply pipe 334b, the second reactive gas supply pipe 334a, and the second reactive gas supply nozzle 334. Also, in this case, N₂ gas is supplied into the fourth zone from gas supply holes 234h via the inert gas supply pipe 234b, the first reactive gas supply pipe 234a, and the first reactive gas supply nozzle 234. Accordingly, the O₃ gas supplied into the process chamber 201 may be prevented from flowing into the first reactive gas supply nozzle 234.

Next, in step 4, N₂ gas which is a second purge gas is supplied into the fourth zone not only from the gas supply holes 334h via the inert gas supply pipe 334b, the second reactive gas supply pipe 334a, and the second reactive gas supply nozzle 334, but also from the gas supply holes 234h via the inert gas supply pipe 234b, the first reactive gas supply pipe 234a, and the first reactive gas supply nozzle 234.

After the zirconium oxide film is formed to a predetermined thickness in all the first to fourth zones, the valves 261d to 264d, 261b to 264b, 361d to 364d, and 361b to 364b are opened in a state in which the valves 261c to 264c, 261a to 264a, 361c to 364c, and 361a to 364a are closed, and N₂ gas is supplied as an inert gas into the process chamber 201 from the inert gas supply pipes 231b to 234b and 331b to 334b and then exhausted from the exhaust pipe 271. Thus, a gas or byproducts that remain in the process chamber 201 are discharged from the inside of the process chamber 201, and an atmosphere in the process chamber 201 is replaced with the inert gas. Thereafter, the pressure in the process chamber 201 is recovered to normal pressure (atmospheric pressure recovery).

Then, the seal cap 219 is moved downward by the boat elevator 115 to open the lower end of the reaction tube 203, and the processed wafers 202 are unloaded to the outside of the reaction tube 203 from the lower end of the reaction tube 203 while being retained in the boat 217 (boat unloading). Thereafter, the processed wafers 202 are unloaded from the boat 217 (wafer discharging). Accordingly, the process of forming the zirconium oxide film on the wafers 202 to the predetermined thickness is completed.

In the present embodiment, both the number of zones and the number of steps are set to 4, and the steps are performed at timings offset by one step in each of the zones as described above. That is, in the present embodiment, different processes are simultaneously performed in the zones. In other words, in the present embodiment, the same process is not simultaneously performed and processes are performed in the zones at different timings. That is, in the present embodiment, a cycle including a process of supplying a first reactive gas, a first purge process, a process of supplying a second reactive gas, and a second purge process (steps 1 to 4) to be repeatedly performed in the zones is set asynchronously (is not synchronized) in the zones. Also, in the present embodiment, each of the process of supplying the first reactive gas, the first purge process, the process of supplying the second reactive gas, and the second purge process is always performed in one of the zones at any timing. Also, in the present embodiment, the first purge process or the second purge process is performed in a zone between a zone in which the process of supplying the first reactive gas is performed and a zone in which the process of supplying the second reactive gas is performed.

As described above, in the present embodiment, steps are performed in the zones at timings offset by one step. Thus, an inert gas is supplied as a purge gas into not only a zone adjacent to a zone into which the first reactive gas is supplied, but also a zone adjacent to a zone into which the second reactive gas is supplied. Thus, a gas curtain caused by the inert gas is formed as a barrier, which suppresses mixing of the first reactive gas and the second reactive gas, in a zone between the zone into which the first reactive gas is supplied and the zone into which the second reactive gas is supplied.

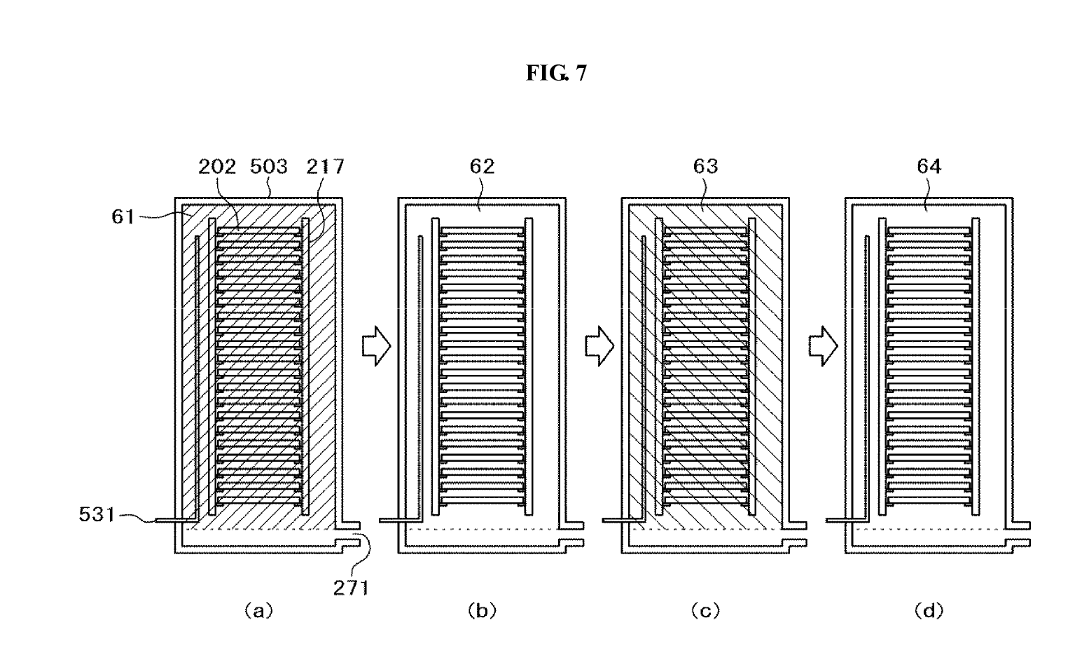

Also, in the present embodiment, both of a zone in which the process of supplying the first reactive gas is performed and a zone in which the process of supplying the second reactive gas is performed are always present at any timing. Thus, the flow rate of a reactive gas to be supplied onto each wafer is higher than in the related art in which the same reactive gas is supplied into an entire process chamber only at a particular timing as in FIG. 7, thereby reducing a time required to supply the reactive gas. That is, an exposure rate of the reactive gas per wafer is increased more than in the related method. Therefore, a time required to form a zirconium-containing layer in step 1 or a time required to oxidize the zirconium-containing layer in step 3, i.e., a film-forming time, may be reduced, thereby increasing the throughput.

Also, in the present embodiment, the number of zones and the number of steps are set to be the same. Thus, the number of reactive gas supply nozzles, the number of reactive gas supply pipes, or the number of inert gas supply pipes may be reduced more than when the number of zones is greater than the number of steps, thereby enabling a gas supply system to be easily configured. Also, the flow rate of a reactive gas per wafer may be set to be higher than when the number of zones is less than the number of steps, thereby reducing a time required to supply the reactive gas. That is, an exposure rate of the reactive gas per wafer may be set to be higher than when the number of zones is less than the number of steps. Accordingly, a time required to form a zirconium-containing layer in step 1 or a time required to oxidize the zirconium-containing layer in step 3, i.e., a film-forming time, may be reduced, thereby increasing the throughput.

The present invention is not limited to the embodiment described above and may be embodied in various different forms without departing from the scope of the present invention. Also, various elements of the embodiment may be arbitrarily and appropriately combined if needed. For example, although the embodiment described above has been described with respect to a batch-type longitudinal apparatus, the present invention is not limited thereto and is applicable to transverse apparatuses or the like. Also, although the embodiment has been described above with respect to a case in which wafers are processed, a target to be processed may be a photomask, a print circuit board, a liquid crystal panel, a compact disc (CD), a magnetic disk, etc.

Although the number of zones is set to 4 in the above-described embodiment, the number of zones may be set to 2, 3, or another value, e.g., 6. For example, if a thin film consisting of three types of elements, such as a three-element thin film, is formed, the number of zones may be set to 6 when three types of reactive gases (a first reactive gas, a second reactive gas, and a third reactive gas) are used. In this case, a process of supplying the first reactive gas, a first purge process, a process of supplying the second reactive gas, a second purge process, a process of supplying the third reactive gas, and a third purge process are always performed in one of the zones at any timing, so that different processes may be simultaneously performed in the zones. Also, the first purge process, the second purge process, or the third purge process is performed in a zone between a zone in which the process of supplying the first reactive gas is performed, a zone in which the process of supplying the second reactive gas is performed, and a zone in which the process of supplying the third reactive gas is performed, and a gas curtain caused by an inert gas is formed to prevent the reactive gases from being mixed with one another. Also, even if three types of reactive gases are used, the number of zones may be set to 4 when a film may be formed by mixing two reactive gases among the three types of reactive gases. Also, if a three-element thin film is formed, the number of zones may be set to 4 when a film may be formed by mixing two types of reactive gases (a first reactive gas containing a first element and a second reactive gas containing a second element and a third element).

This also applies to when four types of reactive gases are used to form a thin film consisting of four elements, such as a four-element thin film. For example, the thin film may be formed by setting the number of zones to 8. Also, the number of zones may be set to 6 or 4 when the thin film may be formed by mixing at least one gas. Also, the number of zones may be set to 6 when a four-element thin film may be formed using three types of reactive gases (a first reactive gas containing a first element, a second reactive gas containing a second element and a third element, and a third reactive gas containing a fourth element). Also, the number of zones may be set to 4 when a four-element thin film may be formed using two types of reactive gases (a first reactive gas containing a first element and a second element, and a second reactive gas containing a third element and a fourth element).

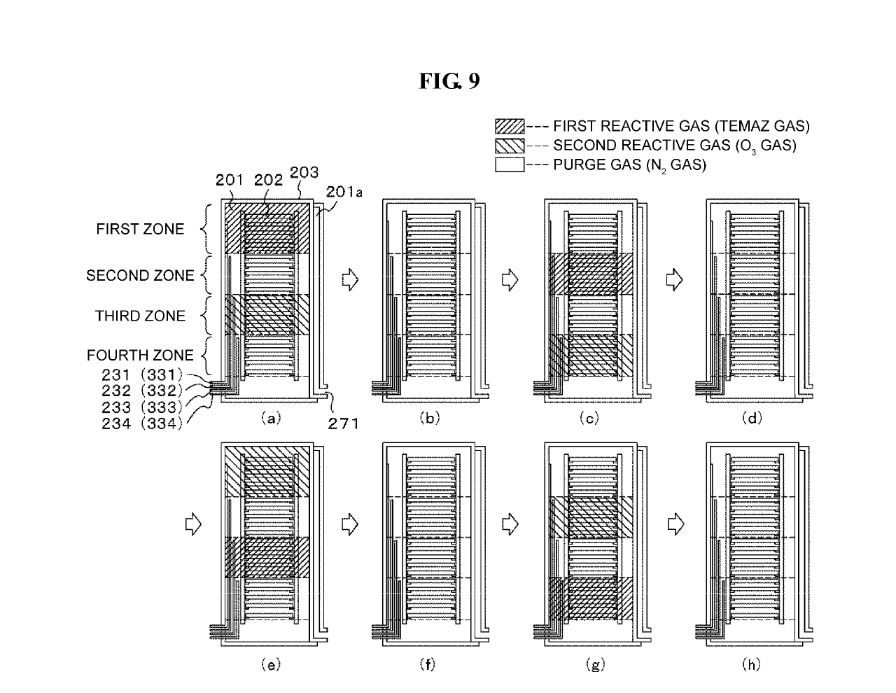

Although the process of supplying the first reactive gas (step 1), the first purge process (step 2), the process of supplying the second reactive gas (step 3), and the second purge process (step 4) are continuously performed in each of zones as illustrated in FIG. 4 in the previous embodiments, a purge process or a vacuum-inhalation process may be performed in all the zones at a time point between continuous steps, i.e., after gases are changed in the zones, as illustrated in FIG. 9. FIG. 9 is a diagram illustrating an atmosphere in a process furnace in a film-forming sequence according to another embodiment of the present invention. In the embodiment of FIG. 9, a purge process is performed in all zones between when gases are changed in the zones and when gases are changed in the zones (see (b), (d), (f), and (h) of FIG. 9).

Also, in the previous embodiments, cases in which tetrakis(ethylmethylamino)zirconium (Zr[N(C₂H₅)(CH₃)]₄, abbreviated as ‘TEMAZ’) which is a source containing zirconium (Zr) is used as the first reactive gas have been described. Alternatively, an organic source, such as tetrakis(dimethylamino)zirconium (Zr[(N(CH₃)₂)₄, abbreviated as ‘TDMAZ’), tetrakis(diethylamino)zirconium (Zr[N(C₂H₅)₂]₄, abbreviated as ‘TDEAZ’), etc., or an inorganic source, such as zirconium tetrachloride (ZrCL₄), etc., may be used as the first reactive gas. Also, in the embodiment, a case in which N₂ gas which is an inert gas is used as a purge gas or a carrier gas has been described above, but a rare gas, such as Ar, He, Ne, or Xe, may be used.

Also, in the embodiment, a case in which ozone (O₃) gas which is an oxidizing gas is used as the second reactive gas has been described, but oxygen (O₂) gas which is an oxidizing gas, nitrogen monoxide (NO) gas, nitrous oxide (N₂O) gas, or vapor (H₂O) may be used. That is, at least one gas selected from the group consisting of O₂ gas, O₃ gas, H₂O gas, NO gas, and N₂O gas may be used as the oxidizing gas.

Also, although, a case in which a ZrO₂ film is formed using TEMAZ and O₃ has been described in the embodiment, the present invention is not limited thereto. For example, the present invention is applicable to forming another high-k film, e.g., an HfO₂ film formed of TEMAH and H₂O, a TiO₂ film formed using TiCl₄ and H₂O, etc. Also, the present invention is applicable to forming a metal film, e.g., a TiN film formed using TiCl₄ and NH₃, a TaN film formed using TaCl₅ and NH₃, a HfN film formed using HfCl₄ and NH₃, a ZrN film formed using ZrCl₄ and NH₃, a TiC film formed using TiCl₄ and a carbon source such as C₃H₆, a TiCN film formed using TiCl₄, a carbon source such as C₃H₆ and NH₃, a TiAlN film formed using TiCl₄, Al(CH₃)₃, and NH₃, etc. Also, the present invention is applicable to forming a pure metal film, e.g., a Ni film formed using Ni(PF₃)₄ and H₂, a Ru film formed using Ru(C₅H₄C₂H₅)₂ and O₂, etc.

As described above, not only a source containing zirconium (Zr) but also a source containing another element, e.g., titanium (Ti), tantalum (Ta), hafnium (Hf), nickel (Ni), ruthenium (Ru), silicon (Si), etc., may be used as the first reactive gas. Also, not only an oxidizing gas but also a reducing gas such as ammonia (NH₃) gas may be used as the second reactive gas. Not only ammonia (NH₃) gas but also diazene (N₂H₂) gas, hydrazine (N₂H₄) gas, N₃H₈ gas, hydrogen (H₂) gas, deuterium (D₂) gas, methane (CH₄) gas, etc. may be used as the reducing gas according to a process. That is, at least one selected from the group consisting of H₂ gas, D₂ gas, NH₃ gas, CH₄ gas, N₂H₂ gas, N₂H₄ gas, and N₃H₈ gas may be used as the reducing gas.

Also, in the previous embodiment, a case in which a thin film is formed using a batch-type substrate processing apparatus capable of processing a plurality of substrates, e.g., 25 to 150 substrates, at once has been described above. However, the present invention is not limited thereto and is preferably applicable to forming a thin film using a substrate processing apparatus capable of processing a few substrates, e.g., several substrates, at once.

Also, appropriate combinations of the embodiments, the modified examples, or application examples described above may be used.

Also, the present invention may be embodied by changing, for example, a process recipe of an existing substrate processing apparatus. To this end, a process recipe according to the present invention may be installed in an existing substrate processing apparatus via an electrical communication line or a recording medium storing the process recipe, or the process recipe installed in the existing substrate processing apparatus may be replaced with the process recipe according to the present invention by manipulating an input/output device of the existing substrate processing apparatus.

Hereinafter, exemplary embodiments of the present invention are supplementarily added.

(Supplementary Note 1)

According to one aspect of the present invention, there is provided a substrate processing apparatus including: a process chamber divided into a plurality of zones and configured to accommodate a plurality of substrates; a gas supply system configured to supply a first reactive gas, a second reactive gas and an inert gas into each of the plurality of zones of the process chamber; a gas exhaust system configured to exhaust a gas from each of the plurality of zones; and a control unit configured to control the gas supply system and the gas exhaust system to perform a cycle repeatedly in each of the plurality of zones of the process chamber accommodating the plurality of substrates so as to form a thin films on a substrate in each of the plurality of zones, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein the steps performed in the plurality of zones at the same time are different from one another.

(Supplementary Note 2)

In the substrate processing apparatus of Supplementary note 1, the control unit is preferably configured to control the gas supply system and the gas exhaust system not to simultaneously perform the same step of the cycle in the plurality of zones when the thin film is formed.

(Supplementary Note 3)

In the substrate processing apparatus of Supplementary note 1 or 2, the control unit is preferably configured to control the gas supply system and the gas exhaust system to perform each of the steps of the cycle in the plurality of zones at different timings when the thin film is formed.

(Supplementary Note 4)

In the substrate processing apparatus of any one of Supplementary notes 1 to 3, the control unit is preferably configured to control the gas supply system and the gas exhaust system to perform the cycle repeatedly in the plurality of zones in an asynchronous manner in each of the plurality of zones when the thin film is formed.

(Supplementary Note 5)

In the substrate processing apparatus of any one of Supplementary notes 1 to 4, the control unit is preferably configured to control the gas supply system and the gas exhaust system to always perform the first supply step, the first purge step, the second supply step, and the second purge step in any one of the plurality of zones at any timing when the thin film is formed.

(Supplementary Note 6)

In the substrate processing apparatus of any one of Supplementary notes 1 to 5, the control unit is preferably configured to control the gas supply system and the gas exhaust system to perform the first purge step or the second purge step in a zone adjacent to a zone in which the first supply step is performed and a zone adjacent to a zone in which the second supply step is performed, when the thin film is formed.

(Supplementary Note 7)

In the substrate processing apparatus of any one of Supplementary notes 1 to 6, the control unit is preferably configured to control the gas supply system and the gas exhaust system to perform the first purge step or the second purge step in a zone between the zone in which the first supply step is performed and the zone in which the second supply step is performed, when the thin film is formed.

(Supplementary Note 8)

In the substrate processing apparatus of any one of Supplementary notes 1 to 7, the control unit is preferably configured to controls the gas supply system and the gas exhaust system to perform one of the first purge step and the second purge step so as to form a gas curtain by the inert gas in the zone interposed between the zone whereat the step of first supply step is performed and the zone whereat the second supply step is performed to form the thin film.

(Supplementary Note 9)

In the substrate processing apparatus of any one of Supplementary notes 1 to 8, a gas supply hole of the gas supply system and a gas exhaust hole of the gas exhaust system are preferably disposed in each of the plurality of zones.

(Supplementary Note 10)

In the substrate processing apparatus of any one of Supplementary notes 1 to 9, the gas supply hole of the gas supply system in each of the plurality of zones preferably faces the gas exhaust hole of the gas exhaust system in each of the plurality of zones.

(Supplementary Note 11)

In the substrate processing apparatus of any one of Supplementary notes 1 to 10, heating units that heat the inside of the process chamber are preferably respectively installed in the plurality of zones outside the process chamber, and the control unit is preferably configured to control the heating units installed in the respective zones to individually perform temperature control.

(Supplementary note 12)

The substrate processing apparatus of any one of Supplementary notes 1 to 11 further includes: a reaction tube having a cylindrical shape and defining the process chamber, the reaction tube being disposed vertically in a lengthwise direction thereof; and a partition plate protruding from an inner wall of the reaction tube toward a center of the reaction tube at each of boundary regions between the plurality of zones.

(Supplementary Note 13)

In the substrate processing apparatus of any one of Supplementary notes 1 to 12, the process chamber is preferably demarcated by the reaction tube which has a cylindrical shape and the lengthwise direction of which is the same as the vertical direction, the gas supply system preferably includes a gas supply nozzle which extends in the vertical direction in the reaction tube, the gas supply nozzle preferably includes a plurality of gas supply holes that open toward the center of the reaction tube, the gas exhaust system preferably includes a plurality of gas exhaust holes formed to extend perpendicularly to a side of the reaction tube opposite to the gas supply nozzle in the reaction tube, and the gas exhaust holes and the gas supply holes are preferably configured to be horizontally located between adjacent substrates accommodated in the reaction tube.

(Supplementary note 14)

According to another aspect of the present invention, there is provided a method of manufacturing a semiconductor device, including: (a) accommodating a plurality of substrates in a process chamber divided into a plurality of zones; and (b) forming a thin film on the substrates in each of the plurality of zones by repeatedly performing a cycle in each of the plurality of zones of the process chamber accommodating the plurality of substrates, the cycle including: supplying a first reactive gas; supplying an inert gas to discharge the first reactive gas; supplying a second reactive gas; and supplying the inert gas to discharge the second reactive gas, wherein the steps performed in the plurality of zones at the same time are different from one another in the step (b).

(Supplementary Note 15)

In the method of Supplementary note 14, preferably, the same step of the cycle is not simultaneously performed in the plurality of zones in the step (b).

(Supplementary Note 16)

In the method of Supplementary note 14 or 15, the steps of the cycle are preferably performed in the plurality of zones at different timings in the step (b).

(Supplementary Note 17)

In the method of any one of Supplementary notes 14 to 16, the control unit is preferably configured to control the gas supply system and the gas exhaust system to perform the cycle in the plurality of zones in an asynchronous manner in each of the plurality of zones in the step (b).

(Supplementary Note 18)

In the method of any one of Supplementary notes 14 to 17, the first supply step, the first purge step, the second supply step, and the second purge step are preferably performed in any one of the plurality of zones at any timing, in the step (b).

(Supplementary Note 19)

In the method of any one of Supplementary notes 14 to 18, the first purge step or the second purge step is preferably performed in a zone adjacent to a zone in which the first supply step is performed and a zone adjacent to a zone in which the second supply step is performed, in the step (b).

(Supplementary Note 20)

In the method of any one of Supplementary notes 14 to 19, the first purge step or the second purge step is preferably performed in a zone between the zone in which the first supply step is performed and the zone in which the second supply step is performed, in the step (b).

(Supplementary Note 21)

In the method of any one of Supplementary notes 14 to 20, the first purge step or the second purge step is preferably performed so as to form a gas curtain by the inert gas in the zone between the zone in which the first supply step is performed and the zone in which the second supply step is performed, in the step(b).

(Supplementary note 22)

According to still another aspect of the present invention, there is provided a substrate processing method including: (a) accommodating a plurality of substrates in a process chamber divided into a plurality of zones; and (b) forming a thin film on the plurality of substrates in each of the plurality of zones by performing a cycle repeatedly in each of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein the steps performed in the plurality of zones at the same time are different from one another in the step (b).

(Supplementary note 23)

According to yet another aspect of the present invention, there is provided a program that causes a computer to perform: (a) accommodating a plurality of substrates in a process chamber, divided into a plurality of zones; and (b) forming a thin film on the plurality of substrates in each of the plurality of zones by performing a cycle repeatedly in each of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein the steps performed in the plurality of zones at the same time are different from one another in the step (b).

(Supplementary note 24)

According to yet another aspect of the present invention, there is provided a non-transitory computer-readable recording medium storing a program that causes a computer to perform: (a) accommodating a plurality of substrates in a process chamber divided into a plurality of zones; and (b) forming a thin film on the plurality of substrates in each of the plurality of zones by performing a cycle repeatedly in each of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas, wherein the steps performed in the plurality of zones at the same time are different form one another in the sequence (b).

1. A substrate processing apparatus comprising:
a process chamber divided into a plurality of zones and configured to accommodate a plurality of substrates;
a gas supply system configured to supply a first reactive gas, a second reactive gas and an inert gas into each of the plurality of zones of the process chamber;
a gas exhaust system configured to exhaust a gas from each of the plurality of zones; and
a control unit configured to control the gas supply system and the gas exhaust system to perform a cycle repeatedly in each of the plurality of zones of the process chamber accommodating the plurality of substrates so as to form thin films on the plurality of substrates in each of the plurality of zones, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas,
wherein the steps performed in the plurality of zones at the same time are different from one another.

2. The substrate processing apparatus of claim 1, wherein the control unit is configured to control the gas supply system and the gas exhaust system to perform the cycle repeatedly in each of the plurality of zones in an asynchronous manner to form the thin film in each of the plurality of zones.

3. The substrate processing apparatus of claim 2, wherein the control unit is configured to control the gas supply system and the gas exhaust system to perform the first purge step or the second purge step in a zone interposed between a zone whereat the first supply step is performed and a zone whereat the second supply step is performed to form the thin film.

4. The substrate processing apparatus of claim 3, wherein the control unit is configured to control the gas supply system and the gas exhaust system to perform the first purge step or the second purge step so as to form a gas curtain by the inert gas in the zone interposed between the zone whereat the step of first supply step is performed and the zone whereat the second supply step is performed to form the thin film.

5. The substrate processing apparatus of claim 4, wherein a gas supply hole of the gas supply system and a gas exhaust hole of the gas exhaust system are disposed in each of the plurality of zones.

6. The substrate processing apparatus of claim 5, wherein the gas supply hole of the gas supply system in each of the plurality of zones faces the gas exhaust hole of the gas exhaust system in each of the plurality of zones.

7. The substrate processing apparatus of claim 6, comprising:
a reaction tube having a cylindrical shape and defining the process chamber, the reaction tube being disposed vertically in a lengthwise direction thereof; and
a partition plate protruding from an inner wall of the reaction tube toward a center of the reaction tube at each of boundary regions between the plurality of zones.

8. A substrate processing method comprising:
(a) accommodating a plurality of substrates in a process chamber divided into a plurality of zones; and
(b) forming a thin film on the plurality of substrates in each of the plurality of zones by performing a cycle repeatedly in each of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas,
wherein the steps performed in the plurality of zones at the same time are different from one another in the step (b).

9. A method of manufacturing a semiconductor device, comprising:
(a) accommodating a plurality of substrates in a process chamber divided into a plurality of zones; and
(b) forming a thin film on the plurality of substrates in each of the plurality of zones by performing a cycle repeatedly of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas,
wherein the steps performed in the plurality of zones at the same time are different from one another in the step (b).

10. A non-transitory computer-readable recording medium storing a program that causes a computer to perform:
(a) accommodating a plurality of substrates in a process chamber divided into a plurality of zones; and
(b) forming a thin film on the plurality of substrates in each of the plurality of zones by performing a cycle repeatedly in each of the plurality of zones of the process chamber accommodating the plurality of substrates, the cycle including: a first supply step of supplying the first reactive gas, a first purge step of discharging the first reactive gas by supplying the inert gas, a second supply step of supplying the second reactive gas, and a second purge step of discharging the second reactive gas by supplying the inert gas,
wherein the steps performed in the plurality of zones at the same time are different from one another in the sequence (b).
